(19) United States
(12) Patent Application Publication
(10) Pub. No.: US 2023/0091632 A1
(43) Pub. Date: Mar. 23, 2023

(54) SEMICONDUCTOR DEVICE AND METHOD OF MANUFACTURING SEMICONDUCTOR DEVICE

(71) Applicant: ROHM CO., LTD., Ukyo-ku (JP)

(72) Inventors: Satoshi KAGEYAMA, Ukyo-ku (JP); Hiroyuki SHINKAI, Ukyo-ku (JP); Yoshihisa TAKADA, Ukyo-ku (JP); Natsuki SAKAMOTO, Ukyo-ku (JP)

(21) Appl. No.: 17/816,826

(22) Filed: Aug. 2, 2022

(30) Foreign Application Priority Data
Sep. 22, 2021 (JP) 2021-153878

(51) Int. Cl. H01L 23/00; H01L 23/498; H01L 21/48; H01L 21/56

(52) U.S. Cl. CPC H01L 24/81; H01L 23/49805; H01L 23/49838; H01L 24/05; H01L 24/13; H01L 24/02; H01L 21/4846; H01L 24/16; H01L 24/08; H01L 21/568; H01L 2224/0235; H01L 2224/02381; H01L 2224/05548; H01L 2224/13147; H01L 2224/13082; H01L 2224/13155; H01L 2224/13164; H01L 2224/13144; H01L 2224/05647; H01L 2224/05573; H01L 2224/16238; H01L 2224/81411; H01L 2224/8142; H01L 2224/81439; H01L 2224/81191; H01L 2924/014; H01L 2224/81815; H01L 2224/81931; H01L 2224/16058; H01L 2224/08058; H01L 2224/13007; H01L 2224/16014

(57) ABSTRACT

A semiconductor device includes: a resin layer having a resin main surface; a mounting wiring layer arranged on the resin main surface, and having a mounting wiring main surface facing the same side as the resin main surface and a mounting wiring back surface facing the side of the resin main surface; a semiconductor element including an element wiring layer which is mounted on the mounting wiring main surface, has an element wiring main surface facing the side of the resin layer, and is connected to the mounting wiring layer; and a sealing resin which seals the mounting wiring layer and the semiconductor element, wherein the mounting wiring main surface and the element wiring main surface are rough surfaces having a larger surface roughness than the mounting wiring back surface.

### CROSS-REFERENCE TO RELATED APPLICATION

This application is based upon and claims the benefit of priority from Japanese Patent Application No. 2021-153878, filed on Sep. 22, 2021, the entire contents of which are incorporated herein by reference.

### TECHNICAL FIELD

The present disclosure relates to a semiconductor device and a method of manufacturing the semiconductor device.

### BACKGROUND

Conventionally, a semiconductor device has been miniaturized along with the miniaturization of electronic apparatuses. The semiconductor device disclosed in the related art includes a rectangular die pad, a plurality of leads arranged around the die pad, a semiconductor chip mounted on the die pad, and a sealing resin that seals the semiconductor chip. The plurality of leads are wirings that electrically connect the semiconductor chip and the outside of the semiconductor device.

By the way, the adhesion between the leads and the sealing resin may be a cause of peeling which occurs between the leads and the sealing resin. Therefore, there is room for improvement in adhesion.

### SUMMARY

Some embodiments of the present disclosure provide a semiconductor device and a method of manufacturing the semiconductor device capable of improving adhesion.

According to one embodiment of the present disclosure, a semiconductor device includes: a resin layer having a resin main surface; a mounting wiring layer arranged on the resin main surface, and having a mounting wiring main surface facing the same side as the resin main surface and a mounting wiring back surface facing the side of the resin main surface; a semiconductor element including an element wiring layer which is mounted on the mounting wiring main surface, has an element wiring main surface facing the side of the resin layer, and is connected to the mounting wiring layer; and a sealing resin which seals the mounting wiring layer and the semiconductor element, wherein the mounting wiring main surface and the element wiring main surface are rough surfaces having a larger surface roughness than the mounting wiring back surface.

### BRIEF DESCRIPTION OF DRAWINGS

FIG. 1 is a perspective view showing an example of a semiconductor device.

FIG. 2 is a cross-sectional view of a semiconductor device of a first embodiment.

FIG. 3 is a partially enlarged cross-sectional view of the semiconductor device shown in FIG. 2.

FIG. 4 is a partially enlarged cross-sectional view of the semiconductor device shown in FIG. 2.

FIG. 5 is a cross-sectional view showing surface states of a sealing resin of a rewiring layer and a wiring layer of the semiconductor element shown in FIG. 2.

FIG. 6 is a cross-sectional view showing surface states of a mounting wiring and the sealing resin of the semiconductor device shown in FIG. 2.

FIG. 7 is a schematic cross-sectional view showing an exemplary manufacturing process of the semiconductor device shown in FIG. 2.

FIG. 8 is a schematic cross-sectional view showing a manufacturing process subsequent to FIG. 7.

FIG. 9 is a schematic cross-sectional view showing a manufacturing process subsequent to FIG. 8.

FIG. 10 is a schematic cross-sectional view showing a manufacturing process subsequent to FIG. 9.

FIG. 11 is a schematic cross-sectional view showing a manufacturing process subsequent to FIG. 10.

FIG. 12 is a schematic cross-sectional view showing a manufacturing process subsequent to FIG. 11.

FIG. 13 is a schematic cross-sectional view showing a manufacturing process subsequent to FIG. 12.

FIG. 14 is a schematic cross-sectional view showing a manufacturing process subsequent to FIG. 13.

FIG. 15 is a schematic cross-sectional view showing a manufacturing process subsequent to FIG. 14.

FIG. 16 is a schematic cross-sectional view showing a manufacturing process subsequent to FIG. 15.

FIG. 17 is a schematic cross-sectional view showing a manufacturing process subsequent to FIG. 16.

FIG. 18 is a schematic cross-sectional view showing a manufacturing process subsequent to FIG. 17.

FIG. 19 is a schematic cross-sectional view showing a manufacturing process subsequent to FIG. 18.

FIG. 20 is a schematic cross-sectional view showing a manufacturing process subsequent to FIG. 19.

FIG. 21 is a cross-sectional view of a semiconductor device of a second embodiment.

FIG. 22 is a partially enlarged cross-sectional view of the semiconductor device shown in FIG. 21.

FIG. 23 is a partially enlarged cross-sectional view of the semiconductor device shown in FIG. 21.

FIG. 24 is a cross-sectional view showing surface states of a rewiring layer and a sealing resin of the semiconductor element shown in FIG. 21.

FIG. 25 is a cross-sectional view showing surface states of a mounting wiring and the sealing resin of the semiconductor device shown in FIG. 21.

FIG. 26 is a schematic cross-sectional view showing an exemplary manufacturing process of the semiconductor device shown in FIG. 21.

FIG. 27 is a schematic cross-sectional view showing a manufacturing process subsequent to FIG. 26.

FIG. 28 is a schematic cross-sectional view showing a manufacturing process subsequent to FIG. 27.

FIG. 29 is a schematic cross-sectional view showing a manufacturing process subsequent to FIG. 28.

FIG. 30 is a characteristic diagram showing adhesion to rough surface roughness and coating film thickness.

### DETAILED DESCRIPTION

Embodiments and modifications will be now described with reference to the drawings. The following embodiments and modifications are examples of configurations and methods for embodying the technical idea, and the materials, shapes, structures, arrangements, dimensions and the like of the respective components are not limited to the following. Various changes can be added to the following embodiments and modifications. The following embodiments and modifications can be implemented in combination unless technically contradictory.

In the present disclosure, “a state where a member A is connected to a member B” includes a case where the member A and the member B are physically directly connected or a case where the member A and the member B are indirectly connected through any other member that does not affect an electrical connection state.

Similarly, “a state where a member C is installed between a member A and a member B” includes a case where the member A and the member C or the member B and the member C are directly connected or a case where the member A and the member C or the member B and the member C are directly connected through any other member that does not affect an electrical connection state.

### First Embodiment

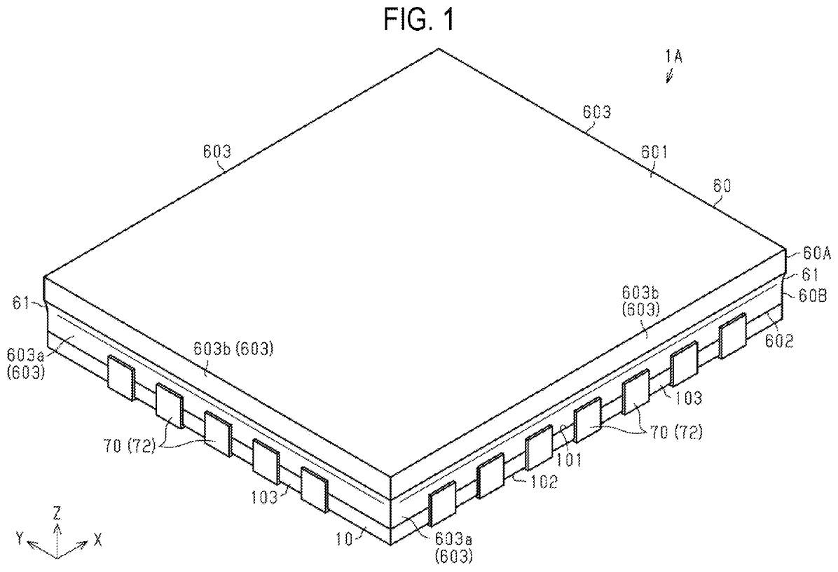

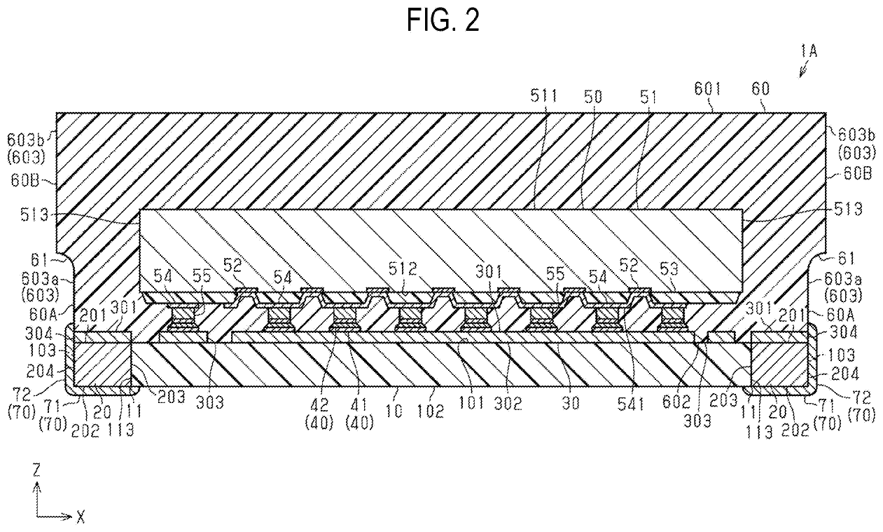

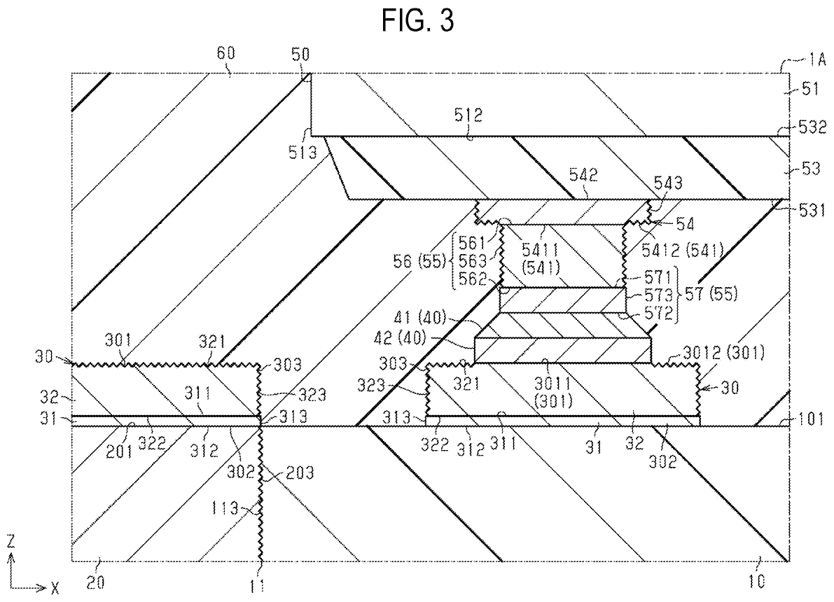

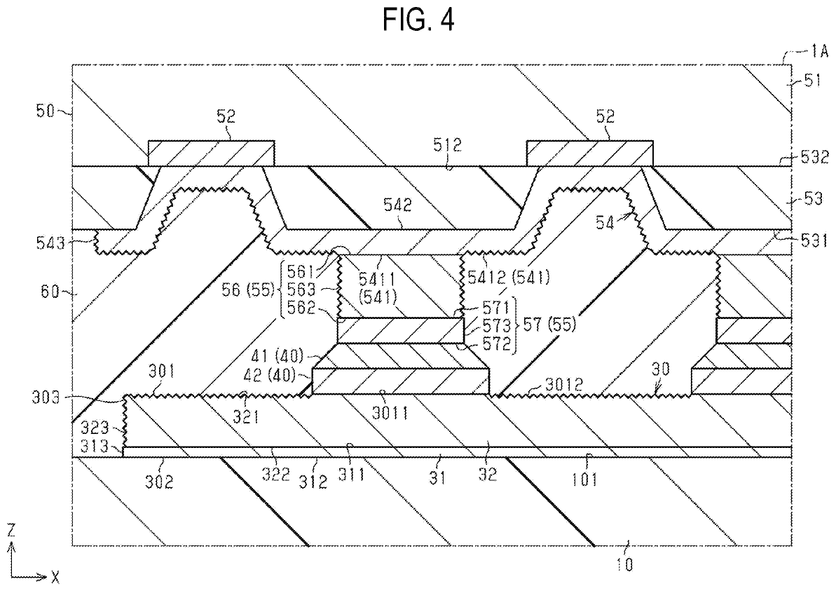

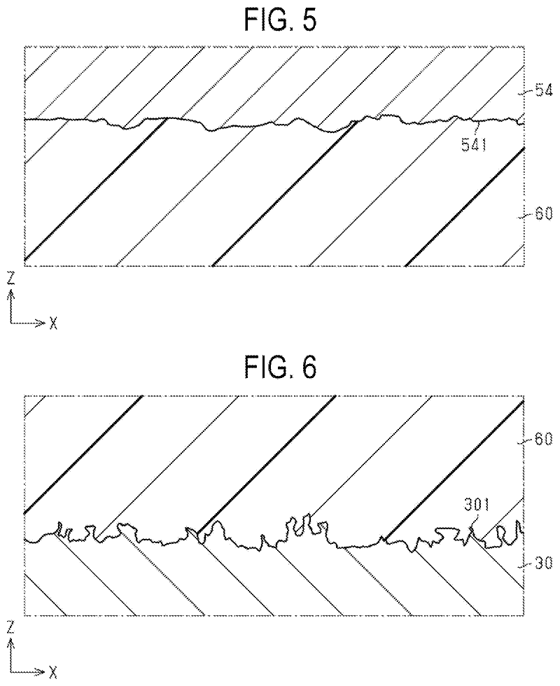

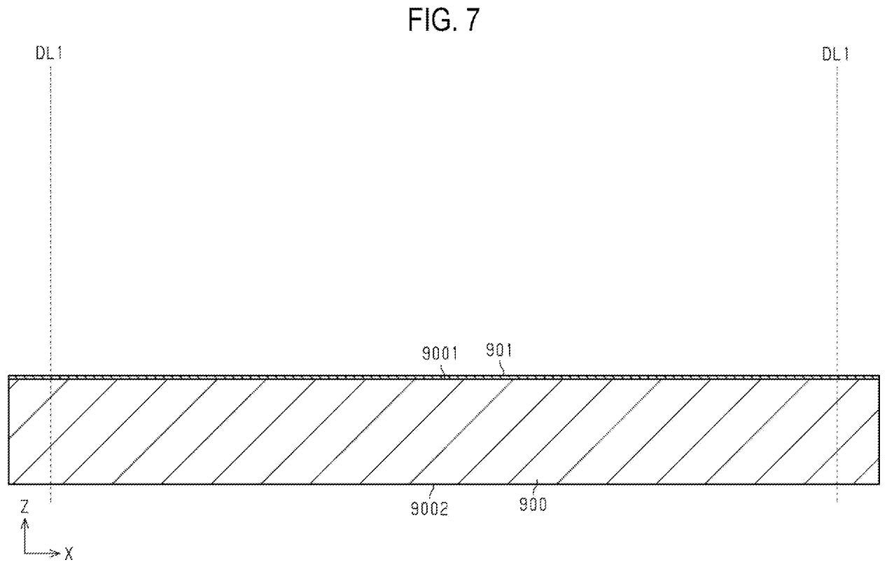

Hereinafter, a first embodiment will be described. FIG. 1 is a perspective view showing an appearance of a semiconductor device 1A of a first embodiment. FIG. 2 is a cross-sectional view of the semiconductor device 1A of the present embodiment. FIGS. 3 and 4 are partially enlarged cross-sectional views of the semiconductor device 1A. FIG. 5 is a cross-sectional view showing surface states of an element wiring layer 54 of a semiconductor element 50 and a sealing resin 60. FIG. 6 is a cross-sectional view showing surface states of a mounting wiring layer 30 and the sealing resin 60 of the semiconductor device 1A. FIGS. 7 to 20 are cross-sectional views showing an exemplary manufacturing process of the semiconductor device 1A.

### [Configuration of Semiconductor Device]

The semiconductor device 1A shown in these figures is a device that is surface-mounted on the circuit board of various electronic apparatuses. As shown in FIG. 1, the semiconductor device 1A has a rectangular plate shape. Here, for the sake of convenience of explanation, a thickness direction of the semiconductor device 1A is defined as a Z direction. Further, a direction along one side of the semiconductor device 1A, which is orthogonal to the Z direction, is defined as an X direction. Further, a direction orthogonal to both the Z direction and the X direction of the semiconductor device 1A is defined as a Y direction.

As shown in FIGS. 1 to 4, the semiconductor device 1A includes a resin layer 10, a terminal portion 20, a mounting wiring layer 30, a bonding portion 40, a semiconductor element 50, a sealing resin 60, and an external conductive film 70.

### [Resin Layer]

As shown in FIG. 2, the resin layer 10 is a support member that is the basis of the semiconductor device 1A, and is used as a substrate made of resin. The resin layer 10 has a plate shape.

The resin layer 10 has a resin main surface 101, a resin back surface 102, and a plurality of resin side surfaces 103. The resin main surface 101 and the resin back surface 102 face opposite to each other in the Z direction. The resin main surface 101 is flat. The resin back surface 102 is flat. Each resin side surface 103 intersects the resin main surface 101 and the resin back surface 102. The resin side surface 103 faces either the X direction or the Y direction. Each resin side surface 103 is flat. Each resin side surface 103 intersects the resin main surface 101 and the resin back surface 102 and is orthogonal to the resin main surface 101 and the resin back surface 102 in the present embodiment. The resin side surface 103 is connected to the resin main surface 101 and the resin back surface 102.

The resin layer 10 is made of, for example, a material having electrical insulation. As this material, for example, a synthetic resin containing an epoxy resin or the like as a main component can be used. The synthetic resin according to the present embodiment is an epoxy resin containing a filler. The filler is composed of, for example, SiO₂ (silica). The material constituting the resin layer 10 is colored in, for example, black. Cutting marks are formed on the resin main surface 101, the resin back surface 102, and the resin side surface 103, which are the surfaces of the resin layer 10. The filler contained in the material of the resin layer 10 is exposed on the resin main surface 101, the resin back surface 102, and the resin side surface 103, which are the surfaces of the resin layer 10.

The resin layer 10 includes a plurality of through-holes 11 that penetrate the resin layer 10 from the resin main surface 101 to the resin back surface 102 in the Z direction. In the present embodiment, the resin layer 10 includes a plurality of through-holes 11 on each side of the resin side surface 103 of the resin layer 10. Each through-hole 11 has, for example, a rectangular shape when viewed from the Z direction. The shape of the through-hole 11 may be a circular shape or a polygonal shape. Each through-hole 11 extends to the resin side surface 103. That is, each through-hole 11 is opened on the resin side surface 103.

### [Terminal Portion]

The terminal portion 20 is arranged in each through-hole 11. The terminal portion 20 has a terminal main surface 201, a terminal back surface 202, and terminal side surfaces 203 and 204. The terminal main surface 201 and the terminal back surface 202 face opposite to each other in the Z direction. The terminal side surfaces 203 and 204 intersect the terminal main surface 201 and the terminal back surface 202. The terminal side surfaces 203 and 204 are connected to the terminal main surface 201 and the terminal back surface 202.

In the first embodiment, the terminal back surface 202 of the terminal portion 20 is flush with the resin back surface 102 of the resin layer 10. The terminal back surface 202 is an exposed surface exposed from the resin back surface 102 of the resin layer 10. The terminal back surface 202 of the terminal portion 20 may not be flush with the resin back surface 102 of the resin layer 10. The terminal side surface 203 of the terminal portion 20 is in contact with the inner wall surface 113 of the through-hole 11. The terminal side surface 204 of the terminal portion 20 is exposed from the resin side surface 103 of the resin layer 10. The terminal portion 20 is made of a material having electrical conductivity. As the material of the terminal portion 20, for example, Cu (copper), Cu alloy, or the like can be used.

### [Mounting Wiring]

The mounting wiring layer 30 is formed on the resin main surface 101 of the resin layer 10. The mounting wiring layer 30 is made of a material having electrical conductivity and is electrically connected to the terminal portion 20. The mounting wiring layer 30 has a mounting wiring main surface 301, a mounting wiring back surface 302, and mounting wiring side surfaces 303 and 304. The mounting wiring main surface 301 and the mounting wiring back surface 302 face opposite to each other in the Z direction. The mounting wiring side surfaces 303 and 304 face a direction orthogonal to the Z direction. The mounting wiring main surface 301 of the mounting wiring layer 30 faces the same direction as the resin main surface 101 of the resin layer 10. The mounting wiring back surface 302 of the mounting wiring layer 30 faces the same direction as the resin back surface 102 of the resin layer 10. The mounting wiring side surfaces 303 and 304 are connected to the mounting wiring main surface 301 and the mounting wiring back surface 302.

A portion of the mounting wiring back surface 302 is in contact with the resin main surface 101 of the resin layer 10, and the other portion of the mounting wiring back surface 302 is connected to the terminal main surface 201 of the terminal portion 20. A plurality of mounting wiring side surfaces 303 are in contact with the sealing resin 60. The mounting wiring side surface 304 facing the X direction is an exposed side surface exposed from the resin side surface 603 of the sealing resin 60.

### [Bonding Portion]

The bonding portion 40 is provided on the mounting wiring layer 30. The bonding portion 40 conducts to the mounting wiring layer 30. The bonding portion 40 bonds the semiconductor element 50 to the mounting wiring layer 30. The semiconductor element 50 is supported while being spaced apart from the mounting wiring main surface 301 of the mounting wiring layer 30 by the bonding portion 40.

### [Semiconductor Element]

The semiconductor element 50 includes an element substrate 51, an electrode pad 52, an insulating film 53, an element wiring layer 54, and an element electrode 55.

The element substrate 51 has a substrate main surface 511, a substrate back surface 512, and a plurality of substrate side surfaces 513. The substrate main surface 511 and the substrate back surface 512 face opposite to each other in the Z direction. Each substrate side surface 513 faces either the X direction or the Y direction. The substrate main surface 511 faces the mounting wiring main surface 301 of the mounting wiring layer 30. The substrate back surface 512 faces the same direction as the mounting wiring main surface 301 of the mounting wiring layer 30. The substrate side surface 513 is connected to the substrate main surface 511 and the substrate back surface 512.

The semiconductor element 50 is an integrated circuit (IC) such as an LSI (Large Scale Integration). Further, the semiconductor element 50 may be a voltage-controlled element such as an LDO (Low Drop Out), an amplification element such as an operational amplifier, a transistor such as a MOSFET, or a discrete semiconductor element such as a diode or various sensors. For example, in the case of the LSI, the substrate main surface 511 is a surface on which a constituent member for the function of the semiconductor element 50 is formed. The semiconductor element 50 is not limited to an element in which a plurality of constituent members are formed, but may be an element in which a single constituent member is formed, such as a chip capacitor or a chip inductor, or an element in which a constituent member is formed on a base material other than a semiconductor.

The electrode pad 52 is provided on the substrate main surface 511 of the element substrate 51. The insulating film 53 is formed so as to be in contact with the substrate main surface 511. The insulating film 53 is formed so as to be in contact with the peripheral edge portion of the electrode pad 52 and to expose the central portion of the electrode pad 52. A portion of the electrode pad 52 is exposed from the insulating film 53. The insulating film 53 is made of, for example, SiN (silicon nitride). The main surface 531 of the insulating film 53 constitutes the element main surface of the semiconductor element 50. The back surface 532 of the insulating film 53 is in contact with the substrate main surface 511 of the element substrate 51. The substrate back surface 512 of the element substrate 51 constitutes the element back surface of the semiconductor element 50. The substrate side surface 513 of the element substrate 51 constitutes the element side surface of the semiconductor element 50.

The element wiring layer 54 is connected to the electrode pad 52. The element wiring layer 54 extends from the electrode pad 52 to the insulating film 53 and is in contact with the main surface 531 of the insulating film 53. The element wiring layer 54 is made of, for example, Cu, a Cu alloy, or the like.

The element electrode 55 is arranged at a position where it does not overlap with the electrode pad 52 when viewed from the Z direction. That is, the electrode pad 52 and the element electrode 55 are misaligned in a direction intersecting the Z direction. The element electrode 55 is connected to the element wiring layer 54. The element electrode 55 is connected to the bonding portion 40. In this way, the semiconductor element 50 is mounted on the mounting wiring main surface 301 of the mounting wiring layer 30.

### [Sealing Resin]

The sealing resin 60 is in contact with the resin main surface 101 of the resin layer 10 and seals the mounting wiring layer 30, the bonding portion 40, and the semiconductor element 50. The sealing resin 60 is filled between the resin layer 10 and the semiconductor element 50. The sealing resin 60 overlaps with the resin layer 10 when viewed from the Z direction.

The sealing resin 60 has a resin main surface 601, a resin back surface 602, and a resin side surface 603. The resin main surface 601 faces the same direction as the resin main surface 101 of the resin layer 10. The resin back surface 602 faces the opposite side to the resin main surface 601. The resin back surface 602 is in contact with the resin main surface 101 of the resin layer 10. The resin side surface 603 intersects the resin main surface 601 and the resin back surface 602.

The sealing resin 60 includes a first resin portion 60A on a side portion of the resin layer 10 and a second resin portion 60B on the side of the resin main surface 601 in the Z direction. The first resin portion 60A has a first resin side surface 603a constituting a portion of the resin side surface 603, and the second resin portion 60B has a second resin side surface 603b constituting a portion of the resin side surface 603. When viewed from the Z direction, the first resin portion 60A has the same size as the resin layer 10. Further, when viewed from the Z direction, the second resin portion 60B is formed to be larger than the first resin portion 60A. The second resin side surface 603b is located at an outer side than the first resin side surface 603a. In this way, the sealing resin 60 includes a step 61 recessed inside the sealing resin 60 due to a difference in size between the first resin portion 60A and the second resin portion 60B. The step 61 is provided over the entire circumferential direction of the sealing resin 60.

The sealing resin 60 is made of, for example, a resin having electrical insulation. As this resin, for example, a synthetic resin containing an epoxy resin as a main component can be used. Further, the sealing resin 60 is colored in, for example, black. Further, the material and shape of the sealing resin 60 are not limited.

### [External Conductive Film]

The external conductive film 70 includes a first conductive film 71 and a second conductive film 72. The first conductive film 71 is in contact with the terminal back surface 202 of the terminal portion 20. The second conductive film 72 is in contact with the terminal side surface 204 of the terminal portion 20 and the mounting wiring side surface 304 of the mounting wiring layer 30. The external conductive film 70 including the first conductive film 71 and the second conductive film 72 serves as an external connection terminal of the semiconductor device 1A. The external conductive film 70 is composed of, for example, a plurality of metal layers laminated with each other. Examples of the metal layer are a Ni (nickel) layer and an Au (gold) layer. The material of the external conductive film 70 is not limited, and may be configured by laminating, for example, a Ni layer, a Pd (palladium) layer, and an Au layer, or may be Sn (tin).

### [Detailed Explanation of Semiconductor Device]

Next, the details of the mounting wiring layer 30 and the semiconductor element 50 will be described with respect to the semiconductor device 1A of the present embodiment.

As shown in FIG. 3, the terminal side surface 203 of the terminal portion 20 is a rough surface having a larger surface roughness than the terminal main surface 201 of the terminal portion 20. The surface roughness of the terminal side surface 203 is represented by, for example, an arithmetic average roughness Ra. The arithmetic average roughness Ra of the terminal side surface 203 is, for example, 0.3 μm or more.

The terminal portion 20 is formed in the through-hole 11 of the resin layer 10, and the terminal side surface 203 of the terminal portion 20 is in contact with the resin layer 10. The terminal side surface 203 is a rough surface and is formed by, for example, a roughening process. The terminal main surface 201 is a flat surface and is formed by, for example, polishing. The terminal side surface 203 is a rough surface. As a result, it is possible to improve the adhesion between the terminal side surface 203 and the resin layer 10 that is in contact with the terminal side surface 203.

As shown in FIGS. 3 and 4, the mounting wiring main surface 301 and the mounting wiring side surface 303 of the mounting wiring layer 30 are in contact with the sealing resin 60. The mounting wiring back surface 302 of the mounting wiring layer 30 is in contact with the terminal portion 20 or the resin layer 10. The mounting wiring main surface 301 of the mounting wiring layer 30 is a rough surface having a larger surface roughness than the mounting wiring back surface 302 of the mounting wiring layer 30. In the present embodiment, the mounting wiring side surface 303 of the mounting wiring layer 30 is a rough surface having a larger surface roughness than the mounting wiring back surface 302 of the mounting wiring layer 30, like the mounting wiring main surface 301.

In the present embodiment, the bonding portion 40 is arranged on the mounting wiring main surface 301. That is, the mounting wiring main surface 301 includes a covered portion 3011 covered by the bonding portion 40 and an exposed portion 3012 exposed from the bonding portion 40. As described above, the exposed portion 3012 is a rough surface having a larger surface roughness than the mounting wiring back surface 302. The covered portion 3011 is a flat surface having a surface roughness smaller than that of the exposed surface.

As shown in FIGS. 3 and 4, the mounting wiring layer 30 includes a metal layer 31 and a conductive layer 32. The metal layer 31 and the conductive layer 32 are laminated on the resin main surface 101 of the resin layer 10 in this order.

The metal layer 31 is, for example, a conductive layer containing Ti (titanium) as a main component. The metal layer 31 is in contact with the resin main surface 101 of the resin layer 10 and the terminal main surface 201 of the terminal portion 20. The metal layer 31 is formed as a seed layer that forms the conductive layer 32. The conductive layer 32 contains, for example, Cu as a main component.

The metal layer 31 has a main surface 311, a back surface 312, and a side surface 313. The main surface 311 and the back surface 312 face opposite to each other in the Z direction. A plurality of side surfaces 313 face a direction intersecting the Z direction. The surface of the metal layer 31, that is, the main surface 311, the back surface 312, and the side surface 313, is a smooth surface.

The conductive layer 32 is formed on the main surface 311 of the metal layer 31. The conductive layer 32 has a main surface 321, a back surface 322, and a side surface 323. The main surface 321 and the back surface 322 face opposite to each other in the Z direction. A plurality of side surfaces 323 face a direction intersecting the Z direction. Of the plurality of side surfaces 323, a side surface constituting the mounting wiring side surface 303 of the mounting wiring layer 30 is in contact with the sealing resin 60. Of the plurality of side surfaces 323, a side surface constituting the mounting wiring side surface 304 (see FIG. 2) of the mounting wiring layer 30 is exposed from the sealing resin 60.

In the present embodiment, the main surface 321 of the conductive layer 32 containing Cu as a main component constitutes the mounting wiring main surface 301 of the mounting wiring layer 30. That is, the main surface 321 of the conductive layer 32 is a rough surface having a larger surface roughness than the mounting wiring back surface 302. Among the side surfaces 323 of the conductive layer 32, the side surface covered by the sealing resin 60 is a rough surface having a larger surface roughness than the mounting wiring back surface 302, like the main surface 321 of the conductive layer 32. Among the side surfaces 323 of the conductive layer 32, the side surface exposed from the sealing resin 60 is a flat surface.

The main surface 321 of the conductive layer 32 constitutes the mounting wiring main surface 301 of the mounting wiring layer 30. The back surface 312 of the metal layer 31 constitutes the mounting wiring back surface 302 of the mounting wiring layer 30. The thickness of the metal layer 31 is thinner than the thickness of the conductive layer 32. It can be said that the mounting wiring layer 30 is substantially composed of the conductive layer 32. Therefore, it can be said that the mounting wiring side surface 303 of the mounting wiring layer 30 is a rough surface having a larger surface roughness than the mounting wiring back surface 302 of the mounting wiring layer 30.

The bonding portion 40 includes a plating layer 41 formed on the mounting wiring main surface 301 of the mounting wiring layer 30, and a solder layer 42 between the plating layer 41 and the element electrode 55 of the semiconductor element 50. The plating layer 41 is made of a conductive metal material. For example, the plating layer 41 is made of Ni. The solder layer 42 is made of Sn and an alloy containing Sn. This alloy is, for example, a Sn—Ag (silver)-based alloy, a Sn—Sb (antimony)-based alloy, or the like.

The semiconductor element 50 includes the element wiring layer 54 and the element electrode 55. The element wiring layer 54 is formed on the main surface 531 of the insulating film 53. The element wiring layer 54 has an element wiring main surface 541, an element wiring back surface 542, and an element wiring side surface 543. The element wiring main surface 541 faces in the same direction as the main surface 531 of the insulating film 53. That is, the element wiring main surface 541 faces the element wiring main surface 541 of the mounting wiring layer 30. The element wiring back surface 542 faces the side opposite to the element wiring main surface 541. The element wiring back surface 542 is in contact with the main surface 531 of the insulating film 53.

The element wiring main surface 541 of the element wiring layer 54 is a rough surface having a larger surface roughness than the element wiring back surface 542. The surface roughness of the element wiring main surface 541 is equal to the surface roughness of the mounting wiring main surface 301 of the mounting wiring layer 30. That is, the element wiring main surface 541 of the element wiring layer 54 is a rough surface having a larger surface roughness than the mounting wiring back surface 302 of the mounting wiring layer 30. In addition, in the present disclosure, “equal” includes a case where two measured values are the same value, and a case where a difference between two measured values is in a predetermined proportion, for example, 5% or less, of one of the two measured values. In the present embodiment, if a difference in surface roughness between the mounting wiring main surface 301 and the element wiring main surface 541 is within, for example, 5% of the surface roughness of the mounting wiring main surface 301, it can be said that it is equal.

The element wiring side surface 543 of the element wiring layer 54 is a rough surface having a larger surface roughness than the element wiring back surface 542. The surface roughness of the wiring side surface is equal to the surface roughness of the element wiring main surface 541. That is, the element wiring side surface 543 of the element wiring layer 54 is a rough surface having a larger surface roughness than the mounting wiring back surface 302 of the mounting wiring layer 30.

The element electrode 55 is provided on the element wiring main surface 541 of the element wiring layer 54. Therefore, the element wiring main surface 541 of the element wiring layer 54 is partially covered by the element electrode 55. That is, the element wiring main surface 541 includes a covered portion 5411 covered by the element electrode 55 and an exposed portion 5412 not covered by the element electrode 55, that is, exposed from the element electrode 55. As described above, the exposed portion 5412 is a rough surface having a surface roughness larger than that of the mounting wiring back surface 302 of the mounting wiring layer 30. The covered portion 5411 is a flat surface having a smaller surface roughness than the exposed portion 5412.

The exposed portion 5412 of the element wiring main surface 541 of the element wiring layer 54 and the element wiring side surface 543 of the element wiring layer 54 are the surface of the element wiring layer 54. That is, the surface of the element wiring layer 54 is a rough surface having a larger surface roughness than the mounting wiring back surface 302 of the mounting wiring layer 30. The surfaces of the element wiring layer 54, that is, the element wiring main surface 541 (the exposed portion 5412) and the element wiring side surface 543, are in contact with the sealing resin 60.

The element electrode 55 includes a conductive layer 56 and a barrier layer 57. The conductive layer 56 is connected to the element wiring main surface 541 of the element wiring layer 54. The conductive layer 56 is composed of, for example, Cu or a Cu alloy. The conductive layer 56 may include a seed layer. The seed layer is composed of, for example, titanium (Ti)/Cu. The barrier layer 57 is composed of Ni, an alloy containing Ni, or a plurality of metal layers containing Ni. As the barrier layer 57, for example, Ni, Pd, Au, an alloy containing two or more of these metals, and the like can be used.

The conductive layer 56 has a main surface 561, a back surface 562, and a side surface 563. The main surface 561 and the back surface 562 face opposite to each other in the Z direction. The main surface 561 faces the same direction as the element wiring main surface 541 of the element wiring layer 54. The back surface 562 faces the element wiring main surface 541. The side surface 563 intersects the main surface 561 and the back surface 562. The side surface 563 is connected to the main surface 561 and the back surface 562.

The back surface 562 of the conductive layer 56 is in contact with the element wiring main surface 541 of the element wiring layer 54. Further, the main surface 561 of the conductive layer 56 is in contact with the barrier layer 57. The side surface 563 of the conductive layer 56 is a rough surface having a larger surface roughness than the main surface 561 and the back surface 562. In the present embodiment, the surface roughness of the side surface 563 of the conductive layer 56 is equal to the surface roughness of the element wiring main surface 541 of the element wiring layer 54. Therefore, the side surface 563 of the conductive layer 56 is a rough surface having a larger surface roughness than the mounting wiring back surface 302 of the mounting wiring layer 30. The side surface 563 of the conductive layer 56 is in contact with the sealing resin 60.

The barrier layer 57 has a main surface 571, a back surface 572, and a side surface 573. The main surface 571 and the back surface 572 face opposite to each other in the Z direction. The main surface 571 faces the same direction as the main surface 561 of the conductive layer 56. The back surface 572 faces the main surface 561 of the conductive layer 56. The side surface 573 intersects the main surface 571 and the back surface 572. The side surface 573 is connected to the main surface 571 and the back surface 572.

The back surface 572 of the barrier layer 57 is in contact with the main surface 561 of the conductive layer 56. Further, the main surface 571 of the barrier layer 57 is in contact with the solder layer 42 of the bonding portion 40. The side surface 573 of the barrier layer 57 is a flat surface. The side surface 573 of the barrier layer 57 is in contact with the sealing resin 60.

### [Method of Manufacturing Semiconductor Device]

An example of a method of manufacturing the semiconductor device 1A according to the first embodiment will be described with reference to FIGS. 7 to 20. Each referred figure shows a range in which one semiconductor device 1A is formed. For the sake of ease of understanding, in FIGS. 7 to 20, the same constituent elements as those in FIGS. 1 to 6 are denoted by the same reference numerals. Further, the definition of each direction shown in each figure is the same as the definition of the direction shown in FIGS. 1 to 6. Two broken lines DL1 shown in FIGS. 7 to 20 indicate a range in which one semiconductor device 1A is formed.

As shown in FIG. 7, the method of manufacturing the semiconductor device 1A includes a step of preparing a support substrate 900. The support substrate 900 is made of, for example, a Si (silicon) single crystal material. The support substrate 900 has a main surface 9001 and a back surface 9002 facing opposite to each other in the Z direction. As the support substrate 900, a substrate made of a synthetic resin material such as an epoxy resin may be used.

Further, the method of manufacturing the semiconductor device 1A includes a step of forming a seed layer 901. For example, the seed layer 901 is formed on the main surface 9001 of the support substrate 900 by a sputtering method. The seed layer 901 includes, for example, a first layer containing Ti as a main component and a second layer containing Cu as a main component. The first layer is formed on the entire surface of the main surface 9001 of the support substrate 900, and the second layer which is contact with the first layer is formed.

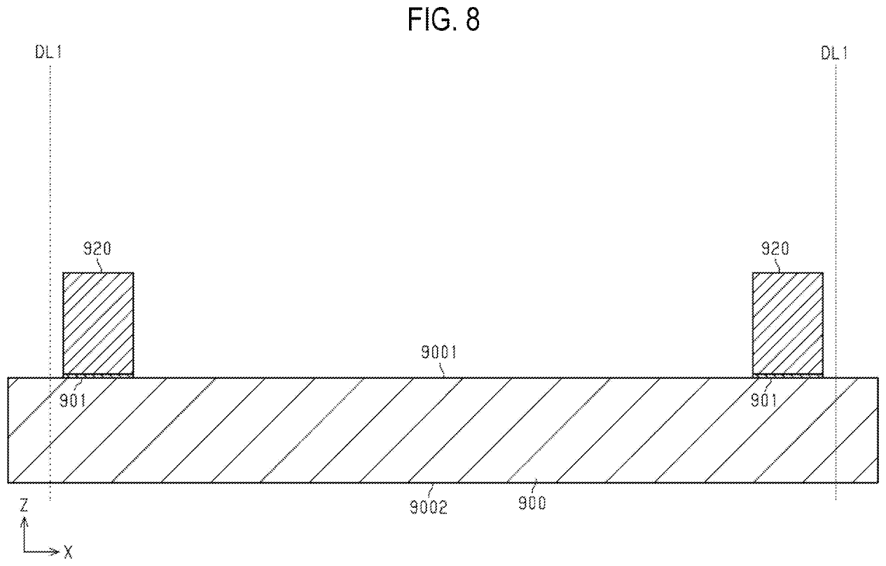

As shown in FIG. 8, the method of manufacturing the semiconductor device 1A includes a step of forming a terminal portion 920. The step of forming the terminal portion 920 includes a step of forming a mask, a step of forming a terminal portion 920, a step of removing the mask, a step of roughening the surface of the terminal portion 920, and a step of removing the seed layer 901. The terminal portion 920 is made of, for example, Cu or an alloy containing Cu as a main component. The terminal portion 920 is formed by, for example, an electrolytic plating method. The terminal portion 920 is the terminal portion 20 in the above-described semiconductor device 1A.

In the step of forming the mask, the mask (not shown) is formed on the seed layer 901 shown in FIG. 7, for example, by photolithography. For example, a photosensitive resist layer is in contact with the seed layer 901, and the resist layer is exposed to light and developed to form a mask having an opening. In the step of forming the terminal portion 920, the terminal portion 920 is formed by, for example, an electrolytic plating method. Terminal portion 920 is formed by precipitating plated metal on the surface of the seed layer, which is exposed from the mask, by an electrolytic plating method using the seed layer as a conductive path. In the step of removing the mask, the mask is removed by using, for example, a stripping solution. In the step of roughening the surface of the terminal portion 920, the support substrate 900 on which the terminal portion 920 is formed is immersed in a roughening solution. As the roughening solution, for example, an alkaline solution can be used. The surface of the terminal portion 920 is made rough by the roughening solution. In the step of removing the seed layer 901, the seed layer 901 exposed from the terminal portion 920 is removed by etching, for example, wet etching.

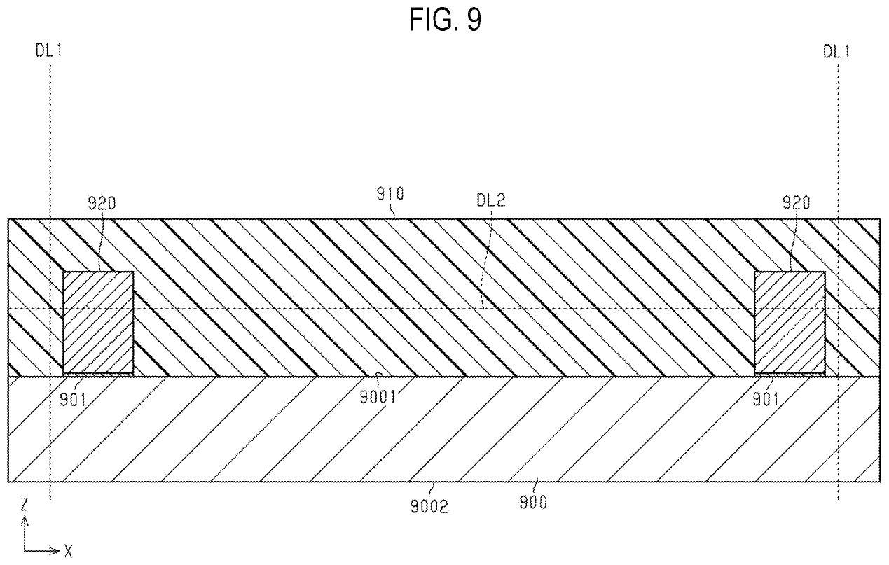

As shown in FIG. 9, the method of manufacturing the semiconductor device 1A includes a step of forming the resin layer 910. The resin layer 910 is formed so as to be in contact with the side surface and the main surface of the terminal portion 920. As the material of the resin layer 910, the material constituting the resin layer 910 shown in FIG. 2 can be used. In the present embodiment, as the material of the resin layer 910, a synthetic resin containing an epoxy resin or the like as a main component can be used.

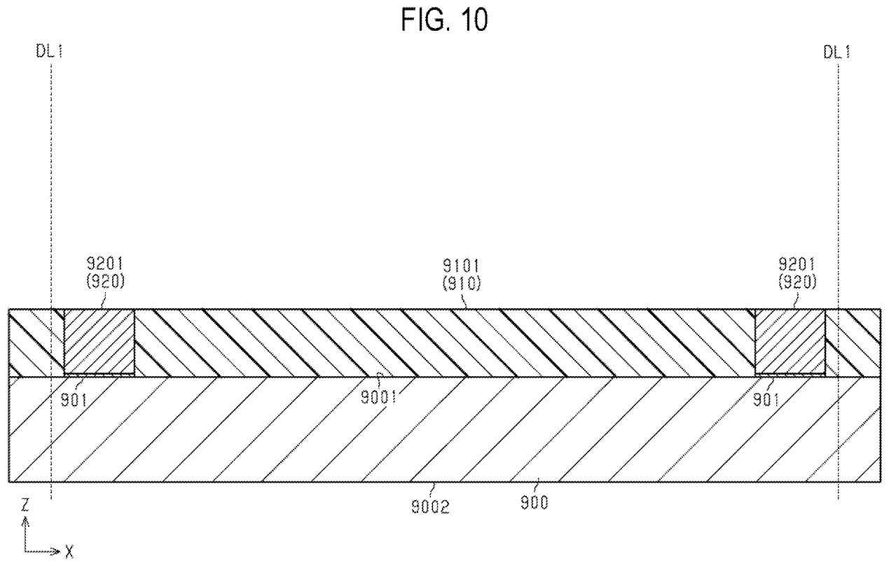

As shown in FIG. 10, the method of manufacturing the semiconductor device 1A includes a step of removing a portion of the resin layer 910 and the terminal portion 920. The resin layer 910 is formed to be thicker than the thickness of the resin layer 10 shown in FIG. 2. For example, the resin layer 910 and the terminal portion 920 are ground to a broken line DL2 shown in FIG. 9. By this grinding, the main surface 9201 of the terminal portion 920 is exposed on the resin main surface 9101 of the resin layer 910. Then, burrs generated on the terminal portion 920 by the grinding are removed from the resin main surface 9101 of the resin layer 910 by etching, for example, wet etching.

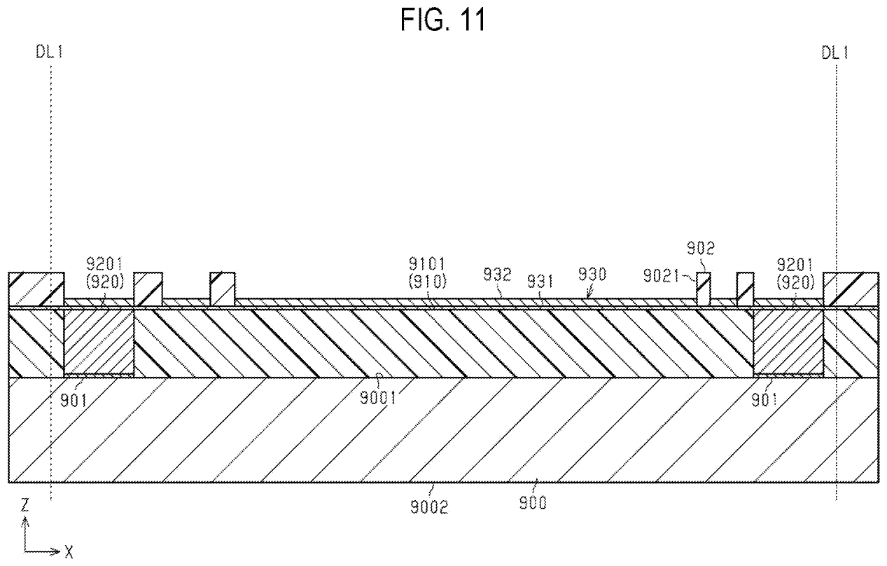

As shown in FIG. 11, the method of manufacturing the semiconductor device 1A includes a step of forming a mounting wiring layer 930. The step of forming the mounting wiring layer 930 includes a step of forming a seed layer 931, a step of forming a mask 902, a step of forming a plating layer 932, and a step of removing the mask 902.

In the step of forming the seed layer 931, the seed layer 931 is formed by, for example, a sputtering method. The seed layer 931 includes a first layer containing Ti as a main component and a second layer containing Cu as a main component. The second layer is in contact with the main surface of the first layer. The seed layer 931 includes the metal layer 31 shown in FIGS. 3 and 4, and a portion of the conductive layer 32. The seed layer 931 is formed so as to be in contact with the resin main surface 9101 of the resin layer 910 and the main surface 9201 of the terminal portion 920. In the step of forming the mask 902, the mask 902 is formed by, for example, photolithography. The mask 902 has an opening 9021 corresponding to the mounting wiring layer 30 shown in FIG. 2. First, for example, a photosensitive resist layer is formed on the main surface of the seed layer 931. As the resist layer, for example, a dry film resist can be used. The resist layer may be composed of a plurality of dry film resists. Next, the resist layer is exposed to light and developed to form the mask 902 having the opening 9021. In the step of forming the plating layer 932, the plating layer 932 is formed by, for example, an electrolytic plating method. The plating layer 932 corresponds to the conductive layer 32 shown in FIGS. 3 and 4. The plating layer 932 is formed by allowing plated metal to grow on the main surface of the seed layer 931 exposed from the mask 902. The plated metal constituting the plating layer 932 contains Cu. In the step of removing the mask 902, the mask 902 is removed by using, for example, a stripping solution.

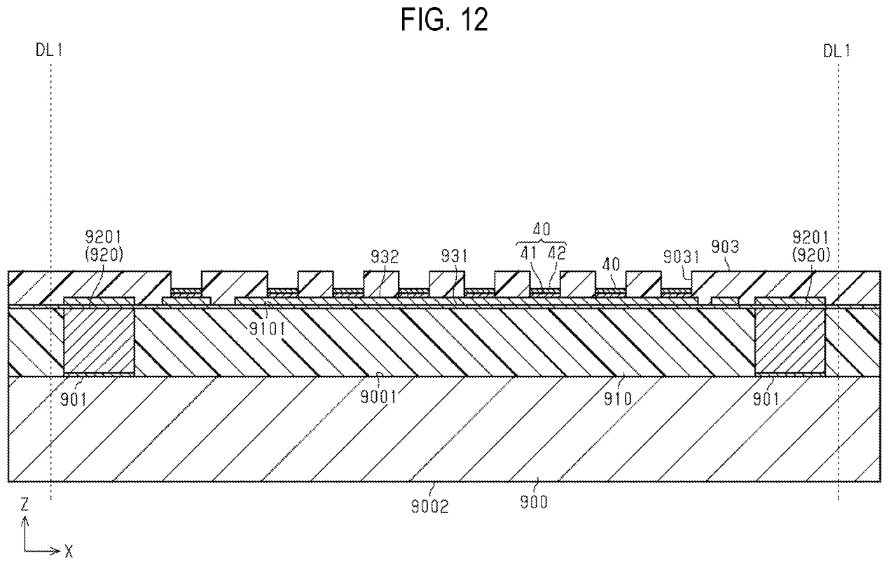

As shown in FIG. 12, the method of manufacturing the semiconductor device 1A includes a step of forming the bonding portion 40. The step of forming the bonding portion 40 includes a step of forming a mask 903 and a step of forming the plating layer 41 and the solder layer 42.

In the step of forming the mask 903, for example, in the same manner as the mask 902 shown in FIG. 11, the mask 903 having an opening 9031 is formed by, for example, photolithography. In the step of forming the plating layer 41 and the solder layer 42, in the same manner as the plating layer 932 shown in FIG. 11, the plating layer 41 and the solder layer 42 are formed in this order by, for example, an electrolytic plating method. The plating layer 41 contains Ni and a Ni alloy. The solder layer 42 contains an alloy containing Sn and Ag.

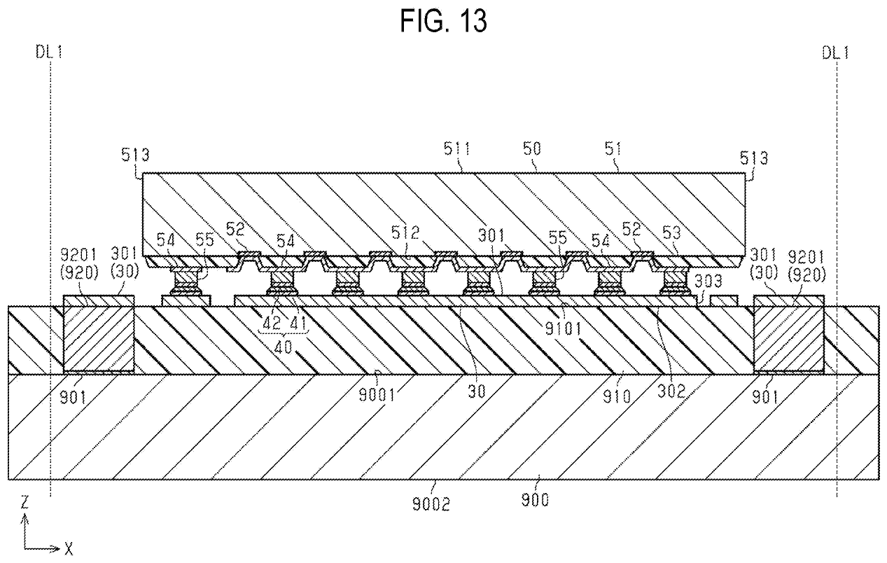

Further, the method of manufacturing the semiconductor device 1A includes a step of removing the mask 903. In the step of removing the mask 903, the mask 903 is removed by using, for example, a stripping solution. Further, the method of manufacturing the semiconductor device 1A includes a step of removing the seed layer 931. In the step of removing the seed layer 931, the seed layer 931 exposed from the plating layer 932 is removed by etching, for example, wet etching. The remaining seed layer 931 and plating layer 932 constitute the mounting wiring layer 30 shown in FIG. 13.

As shown in FIG. 13, the method of manufacturing the semiconductor device 1A includes a step of mounting the semiconductor element 50. The step of mounting the semiconductor element 50 includes a step of flip-chip mounting the semiconductor element 50 and a step of reflowing. The semiconductor element 50 is flip-chip mounted by applying a flux to the element electrode 55 by using, for example, a flip chip bonder. In the step of reflowing, the solder layer 42 shown in FIG. 12 is brought into a liquid phase state by heating, and then is cooled. By these processes, the semiconductor element 50 is mounted on the mounting wiring layer 30 by the bonding portion 40.

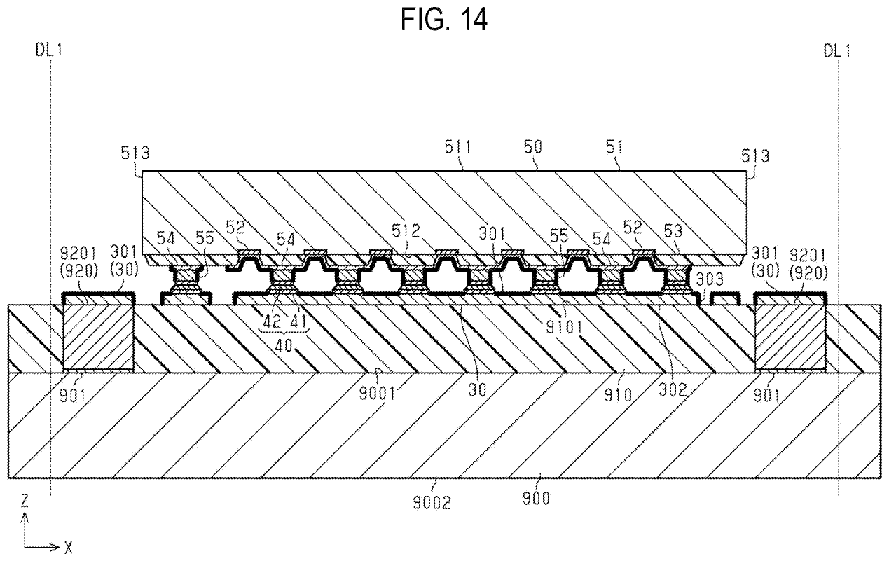

As shown in FIG. 14, the method of manufacturing the semiconductor device 1A includes a step of performing a roughening process. In FIG. 14, a portion to be roughened is indicated by a bold line. The step of performing the roughening process is a process of roughening the surface of the mounting wiring layer 30 and the surface of the element wiring layer 54. In this step, an alkaline solution is used as a roughening solution. The support substrate 900 on which the semiconductor element 50 is mounted is immersed into the roughening solution. The roughening solution (alkaline solution) used here reacts well with Cu constituting the mounting wiring layer 30 (the conductive layer 32 shown in FIGS. 3 and 4) and the element wiring layer 54. Further, this roughening solution is unlikely to react with metal such as Ti, Ni, Sn, and Ag other than Cu. Therefore, the surfaces of the mounting wiring layer 30 (the conductive layer 32) and the element wiring layer 54 made of a material containing Cu are rough surfaces. In the semiconductor element 50 of the present embodiment, the element electrode 55 includes the conductive layer 56 formed of a material containing Cu. Therefore, the side surface 563 of the conductive layer 56 (see FIGS. 3 and 4) becomes a rough surface in this step, like the mounting wiring layer 30 (the conductive layer 32) and the element wiring layer 54.

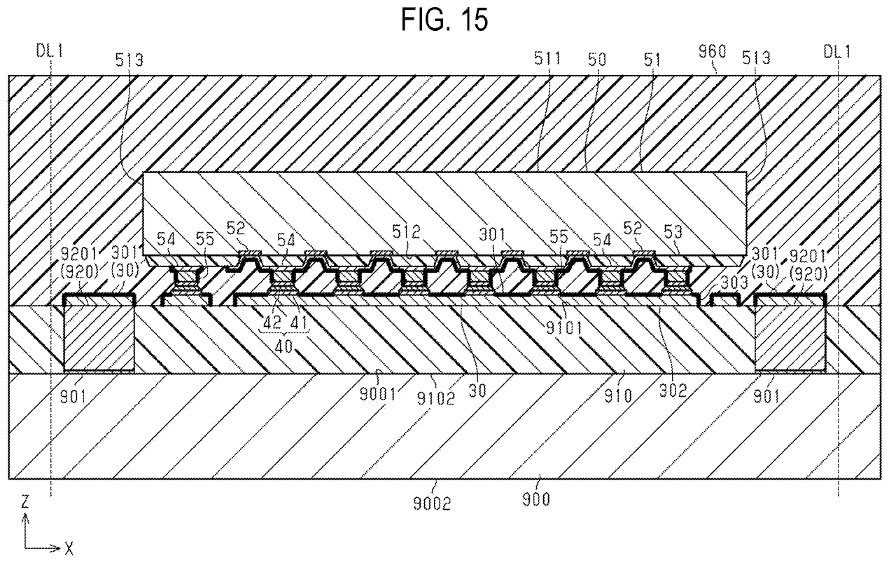

As shown in FIG. 15, the method of manufacturing the semiconductor device 1A includes a step of forming a resin layer 960. The resin layer 960 is a member that becomes the sealing resin 60 shown in FIG. 2. The resin layer 960 is, for example, a synthetic resin containing an epoxy resin as a main material. The resin layer 960 is formed by, for example, compression molding. The resin layer 960 is formed so as to be in contact with the resin main surface 9101 of the resin layer 910 and to seal the semiconductor element 50, the bonding portion 40, and the mounting wiring layer 30. That is, the resin layer 960 is filled between the resin layer 910 and the semiconductor element 50.

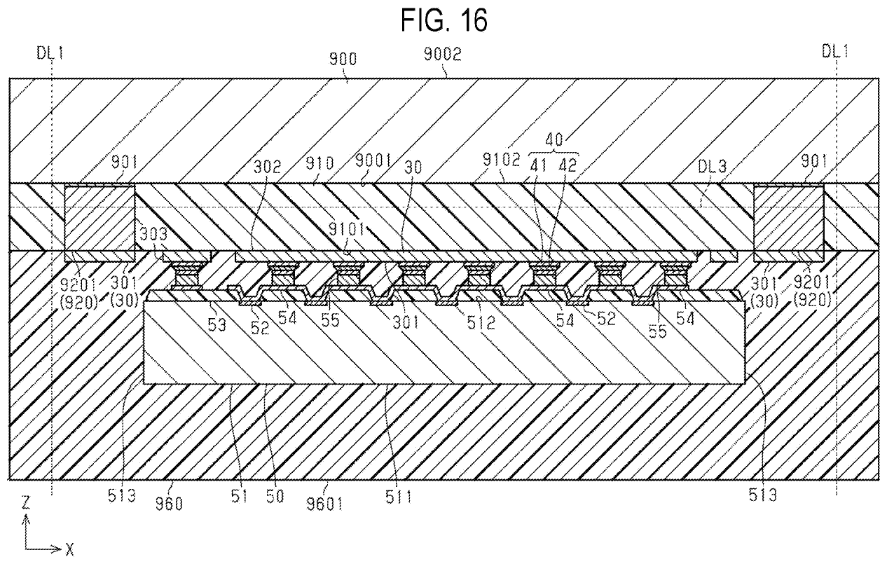

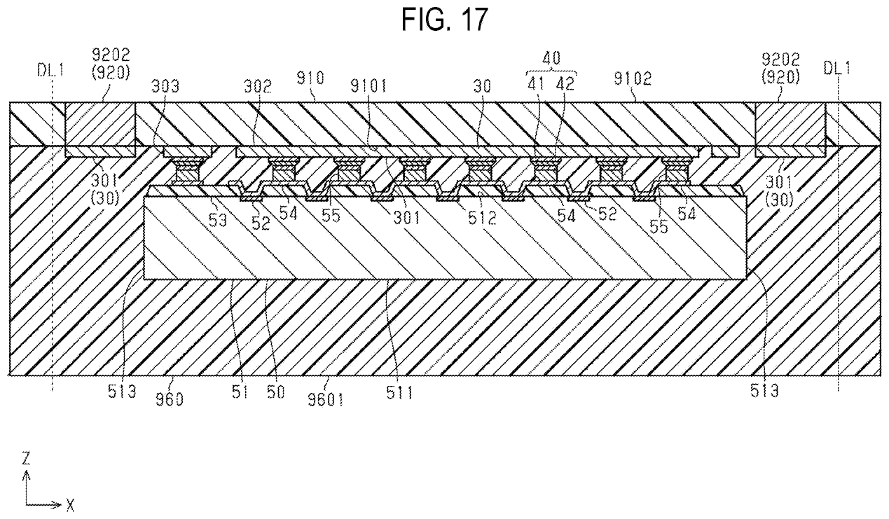

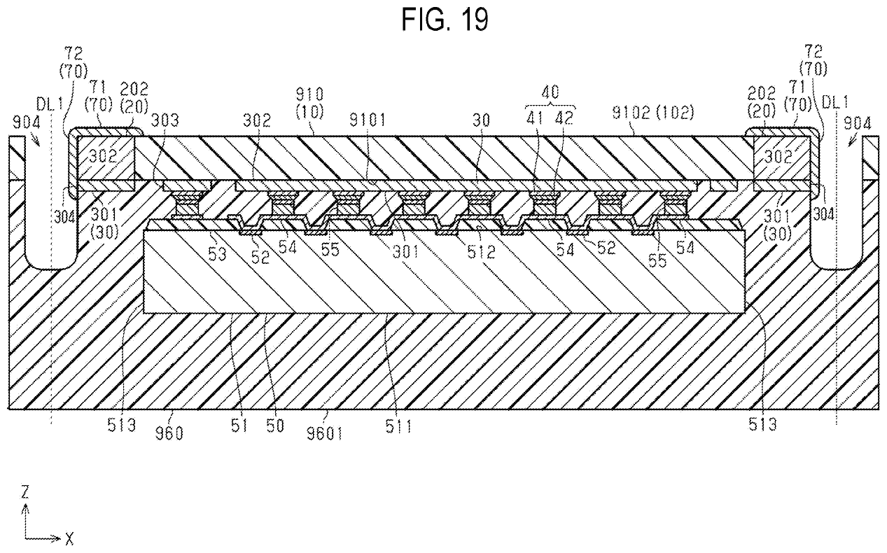

As shown in FIGS. 16 and 17, the method of manufacturing the semiconductor device 1A includes a step of removing the support substrate 900. A dicing tape (not shown) is attached to the main surface 9601 of the resin layer 960. It should be noted that FIG. 17 is shown upside down with respect to FIG. 16. Then, the support substrate 900, the seed layer 901, a portion of the resin layer 910, and a portion of the terminal portion 920 are removed by grinding. At this time, the grinding is performed from the side of the support substrate 900 toward the resin layer 960 to a broken line DL3 shown in FIG. 16. As a result, as shown in FIG. 19, the resin back surface 9102 of the resin layer 910 and the back surface 9202 of the terminal portion 920 are formed. After peeling the support substrate 900 from the resin layer 910, a portion of the resin layer 910, the seed layer 901, and a portion of the terminal portion 920 may be ground.

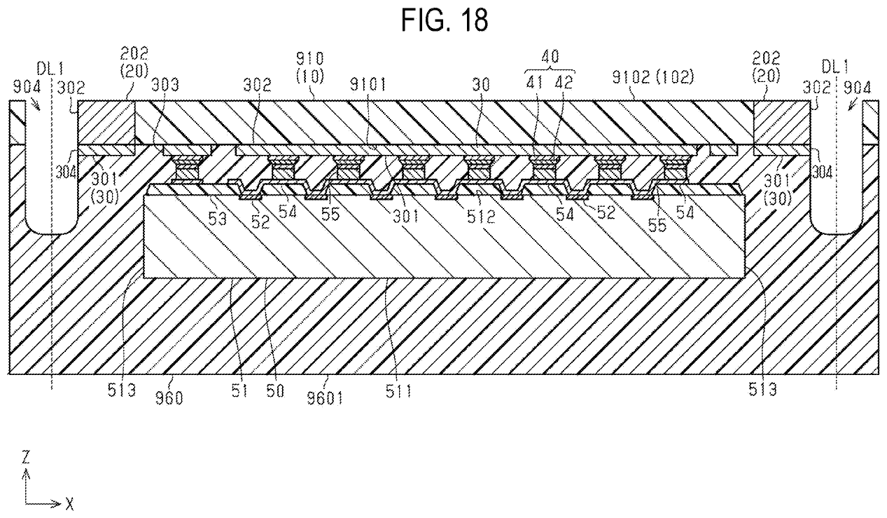

As shown in FIG. 18, the method of manufacturing the semiconductor device 1A includes a step of forming a separation groove 904. In this step, the resin layer 910 is cut and a portion of the resin layer 960 in the Z direction is cut (half-cut). In such cutting of the resin layer 910 and half-cutting of the resin layer 960, for example, a dicing blade is used to cut along a cutting line (broken line) DL1 shown in FIG. 18 from the resin back surface 9102 of the resin layer 910 toward the main surface 9601 of the resin layer 960. By half-cutting the resin layer 960 in this way, the separation groove 904 is formed in the resin layer 960. Then, the terminal portion 20 is formed by the cutting of the resin layer 910 and the half-cutting of the resin layer 960 with the dicing blade. More specifically, the terminal side surface 204 of the terminal portion 20 and the mounting wiring side surface 304 of the mounting wiring layer 30 are formed. The terminal side surface 204 of the terminal portion 20 and the mounting wiring side surface 304 of the mounting wiring layer 30 are exposed to the separation groove 904.

As shown in FIG. 19, the method of manufacturing the semiconductor device 1A includes a step of forming the external conductive film 70. The external conductive film 70 includes the first conductive film 71 which is in contact with the terminal back surface 202 of the terminal portion 20, and the second conductive film 72 which is in contact with the terminal side surface 204 of the terminal portion 20 and the mounting wiring side surface 304 of the mounting wiring layer 30. The second conductive film 72 is formed in the separation groove 904. The external conductive film 70 is composed of plated metal. For example, the external conductive film 70 is formed by precipitating plated metals, for example, Ni, Pd, and Au in this order by an electroless plating method. The configuration and forming method of the external conductive film 70 are not limited to the above method.

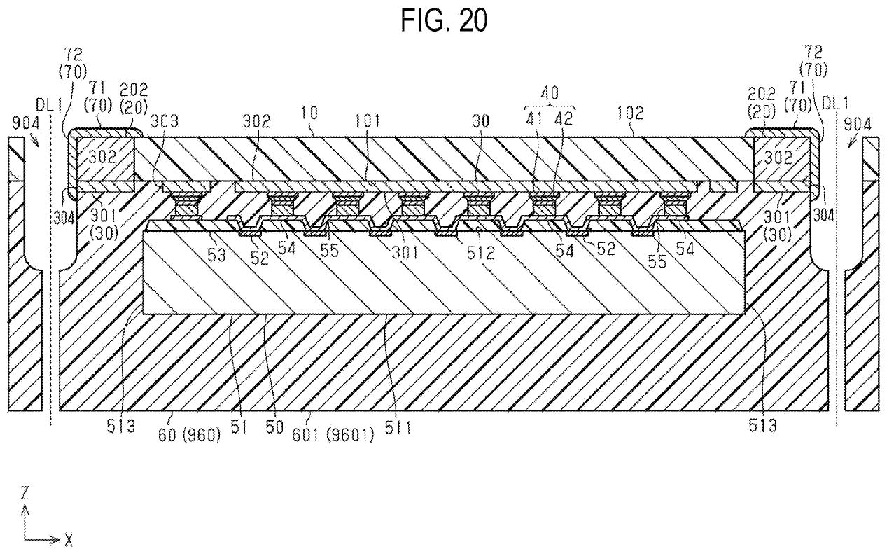

As shown in FIG. 20, the method of manufacturing the semiconductor device 1A includes an individualization step. The resin layer 960 is cut and the semiconductor element 50 is divided into individual pieces as one unit. In the division, the resin layer 960 is cut from the separation groove 904 of the resin layer 960 to the main surface 9601 of the resin layer 960 by, for example, a dicing blade having a width narrower than that of the dicing blade half-cutting the resin layer 960 along the broken line (cutting line) DLL The individual piece is the semiconductor device 1A including the sealing resin 60. As a result, the sealing resin 60 is formed. The semiconductor device 1A is manufactured through the above-described steps.

### (Operation)

Next, the operation of the semiconductor device 1A of the present embodiment will be described. The semiconductor device 1A includes the resin layer 10, the mounting wiring layer 30, the semiconductor element 50, and the sealing resin 60. The resin layer 10 has the resin main surface 101. The mounting wiring layer 30 is arranged on the resin main surface 101 and has the mounting wiring main surface 301 and the mounting wiring back surface 302 facing the side opposite to the mounting wiring main surface 301. The semiconductor element 50 is mounted on the mounting wiring main surface 301, has the element wiring main surface 541 facing the side of the resin layer 10, and includes the element wiring layer 54 connected to the mounting wiring layer 30. The sealing resin 60 seals the mounting wiring layer 30 and the semiconductor element 50.

The mounting wiring main surface 301 is in contact with the sealing resin 60. The mounting wiring main surface 301 of the mounting wiring layer 30 is a rough surface having a larger surface roughness than the mounting wiring back surface 302 of the mounting wiring layer 30. Therefore, the adhesion of the sealing resin 60 to the mounting wiring layer 30 can be improved by the anchor effect of the sealing resin 60 which is in contact with the mounting wiring main surface 301 with respect to the mounting wiring main surface 301 of the mounting wiring layer 30. Then, peeling of the sealing resin 60 from the mounting wiring layer 30 can be suppressed.

The element wiring layer 54 has the element wiring main surface 541 and the element wiring back surface 542 facing the side opposite to the element wiring main surface 541. The element wiring main surface 541 is in contact with the sealing resin 60. The element wiring main surface 541 of the element wiring layer 54 is a rough surface having a larger surface roughness than the element wiring back surface 542 of the element wiring layer 54. Therefore, the adhesion of the sealing resin 60 to the element wiring layer 54 can be improved by the anchor effect of the sealing resin 60 which is in contact with the element wiring main surface 541 with respect to the element wiring main surface 541 of the element wiring layer 54. Then, peeling of the sealing resin 60 from the element wiring layer 54 can be suppressed.

The mounting wiring side surface 303 of the mounting wiring layer 30 is a rough surface having a larger surface roughness than the mounting wiring back surface 302 of the mounting wiring layer 30, like the mounting wiring main surface 301. Therefore, the adhesion of the sealing resin 60 to the mounting wiring side surface 303 can be improved. Then, peeling of the sealing resin 60 from the mounting wiring side surface 303 can be suppressed.

The element electrode 55 of the semiconductor element 50 includes the conductive layer 56 and the barrier layer 57. The conductive layer 56 is composed of, for example, Cu or a Cu alloy. The side surface 563 of the conductive layer 56 is a rough surface having a larger surface roughness than the mounting wiring back surface 302 of the mounting wiring layer 30. Therefore, the adhesion of the sealing resin 60 to the conductive layer 56 can be improved. Then, peeling of the sealing resin 60 from the conductive layer 56 can be suppressed.

The terminal side surface 203 of the terminal portion 20 is a rough surface having a larger surface roughness than the mounting wiring back surface 302 of the mounting wiring layer 30. As a result, the adhesion between the terminal side surface 203 of the terminal portion 20 and the resin layer 10 can be improved. Then, it is possible to suppress the terminal portion 20 from peeling from the resin layer 10.

The semiconductor device 1A includes the external conductive film 70 which is in contact with the exposed surface of the terminal portion 20. The external conductive film 70 allows the semiconductor device 1A to be easily mounted on a circuit board. The external conductive film 70 includes the first conductive film 71 which is in contact with the terminal back surface 202 of the terminal portion 20 and the second conductive film 72 which is in contact with the terminal side surface 204 of the terminal portion 20. It is possible to increase the connection area and be firmly fixed with respect to the circuit board by the first conductive film 71 and the second conductive film 72. Further, since a solder fillet to be connected to the circuit board is formed on the second conductive film 72, it is possible to easily confirm the connection state to the circuit board.

The method of manufacturing the semiconductor device 1A includes the step of roughening the mounting wiring main surface 301 of the mounting wiring layer 30 and the element wiring main surface 541 of the element wiring layer 54 after mounting the semiconductor element 50 on the mounting wiring layer 30. As a result, the number of steps is smaller than in a case where the mounting wiring layer 30 and the element wiring layer 54 are separately provided as side surfaces, and it is possible to easily roughen the mounting wiring layer 30 and the element wiring layer 54.

The method of manufacturing the semiconductor device 1A includes the step of roughening the surface of the terminal portion 920 constituting the terminal portion 920. The surface of the terminal portion 920 is the terminal side surface 203 of the terminal portion 20 of the semiconductor device 1A. As a result, the adhesion between the terminal side surface 203 of the terminal portion 20 and the resin layer 10 can be improved. Then, it is possible to suppress the terminal portion 20 from peeling from the resin layer 10.

### Effects

As described above, according to the present embodiment, the following effects are obtained.

(1-1) The semiconductor device 1A includes the resin layer 10, the mounting wiring layer 30, the semiconductor element 50, and the sealing resin 60. The resin layer 10 has the resin main surface 101. The mounting wiring layer 30 is arranged on the resin main surface 101 and has the mounting wiring main surface 301 and the mounting wiring back surface 302 facing the side opposite to the mounting wiring main surface 301. The semiconductor element 50 is mounted on the mounting wiring main surface 301, has the element wiring main surface 541 facing the side of the resin layer 10, and includes the element wiring layer 54 connected to the mounting wiring layer 30. The sealing resin 60 seals the mounting wiring layer 30 and the semiconductor element 50.

The mounting wiring main surface 301 is in contact with the sealing resin 60. The mounting wiring main surface 301 of the mounting wiring layer 30 is a rough surface having a larger surface roughness than the mounting wiring back surface 302 of the mounting wiring layer 30. Therefore, the adhesion of the sealing resin 60 to the mounting wiring layer 30 can be improved by the anchor effect of the sealing resin 60, which is in contact with the mounting wiring main surface 301, with respect to the mounting wiring main surface 301 of the mounting wiring layer 30. Then, peeling of the sealing resin 60 from the mounting wiring layer 30 can be suppressed.

(1-2) The element wiring layer 54 has the element wiring main surface 541 and the element wiring back surface 542 facing the side opposite to the element wiring main surface 541. The element wiring main surface 541 is in contact with the sealing resin 60. The element wiring main surface 541 of the element wiring layer 54 is a rough surface having a larger surface roughness than the element wiring back surface 542 of the element wiring layer 54. Therefore, the adhesion of the sealing resin 60 to the element wiring layer 54 can be improved by the anchor effect of the sealing resin 60, which is in contact with the element wiring main surface 541, with respect to the element wiring main surface 541 of the element wiring layer 54. Then, peeling of the sealing resin 60 from the element wiring layer 54 can be suppressed.

(1-3) The mounting wiring side surface 303 of the mounting wiring layer 30 is a rough surface having a larger surface roughness than the mounting wiring back surface 302 of the mounting wiring layer 30, like the mounting wiring main surface 301. Therefore, the adhesion of the sealing resin 60 to the mounting wiring side surface 303 can be improved. Then, peeling of the sealing resin 60 from the mounting wiring side surface 303 can be suppressed.

(1-4) The element electrode 55 of the semiconductor element 50 includes the conductive layer 56 and the barrier layer 57. The conductive layer 56 is composed of, for example, Cu or a Cu alloy. The side surface 563 of the conductive layer 56 is a rough surface having a larger surface roughness than the mounting wiring back surface 302 of the mounting wiring layer 30. Therefore, the adhesion of the sealing resin 60 to the conductive layer 56 can be improved. Further, peeling of the sealing resin 60 from the conductive layer 56 can be suppressed.

(1-5) The terminal side surface 203 of the terminal portion 20 is a rough surface having a larger surface roughness than the mounting wiring back surface 302 of the mounting wiring layer 30. As a result, the adhesion between the terminal side surface 203 of the terminal portion 20 and the resin layer 10 can be improved. Further, it is possible to suppress the terminal portion 20 from peeling from the resin layer 10.

(1-6) The semiconductor device 1A includes the external conductive film 70 which is in contact with the exposed surface of the terminal portion 20. The external conductive film 70 allows the semiconductor device 1A to be easily mounted on a circuit board. The external conductive film 70 includes the first conductive film 71 which is in contact with the terminal back surface 202 of the terminal portion 20 and the second conductive film 72 which is in contact with the terminal side surface 204 of the terminal portion 20. It is possible to increase the connection area and be firmly fixed with respect to the circuit board by the first conductive film 71 and the second conductive film 72. Further, since a solder fillet to be connected to the circuit board is formed on the second conductive film 72, it is possible to easily confirm the connection state to the circuit board.

(1-7) The method of manufacturing the semiconductor device 1A includes the step of roughening the mounting wiring main surface 301 of the mounting wiring layer 30 and the element wiring main surface 541 of the element wiring layer 54 after mounting the semiconductor element 50 on the mounting wiring layer 30. As a result, the number of steps is smaller than in a case where the mounting wiring layer 30 and the element wiring layer 54 are separately provided as side surfaces, and it is possible to easily roughen the mounting wiring layer 30 and the element wiring layer 54.

(1-8) The method of manufacturing the semiconductor device 1A includes the step of roughening the surface of the terminal portion 920 constituting the terminal portion 920. The surface of the terminal portion 920 is the terminal side surface 203 of the terminal portion 20 of the semiconductor device 1A. As a result, the adhesion between the terminal side surface 203 of the terminal portion 20 and the resin layer 10 can be improved. Further, it is possible to suppress the terminal portion 20 from peeling from the resin layer 10.

### Second Embodiment

Hereinafter, a second embodiment will be described. A semiconductor device 1B of the present embodiment is mainly different from the semiconductor device 1A of the first embodiment in that the semiconductor device 1B includes a first adhesion layer 81 and a second adhesion layer 82. In the following description, the same constituent members as those in the first embodiment are denoted by the same reference numerals, and some or all of the explanation thereof will be omitted.

### [Schematic Configuration of Semiconductor Device]

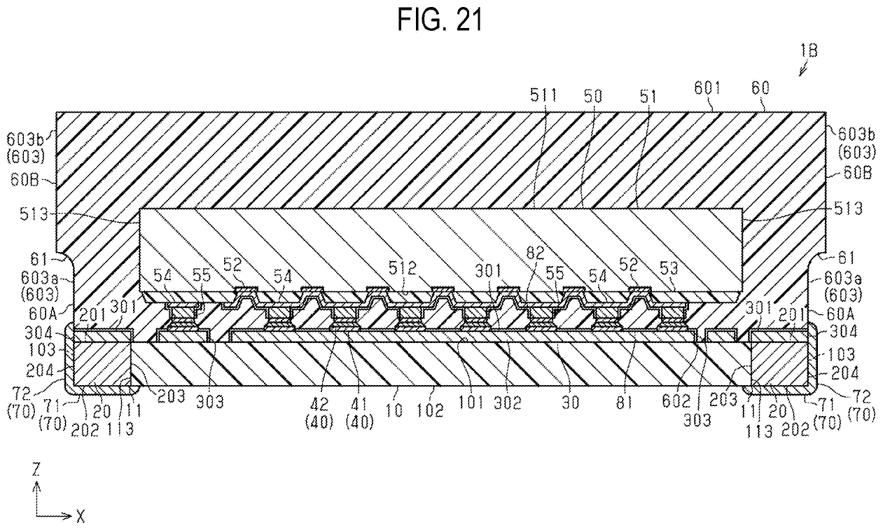

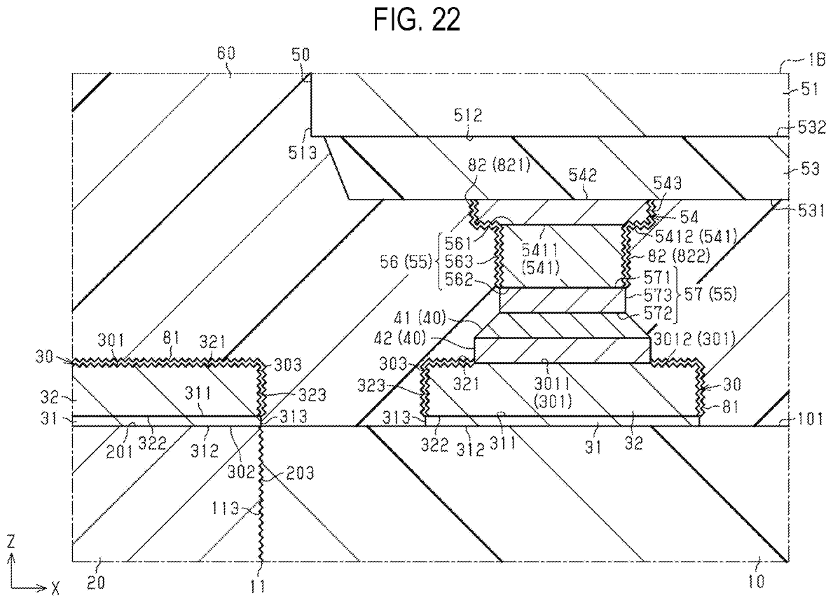

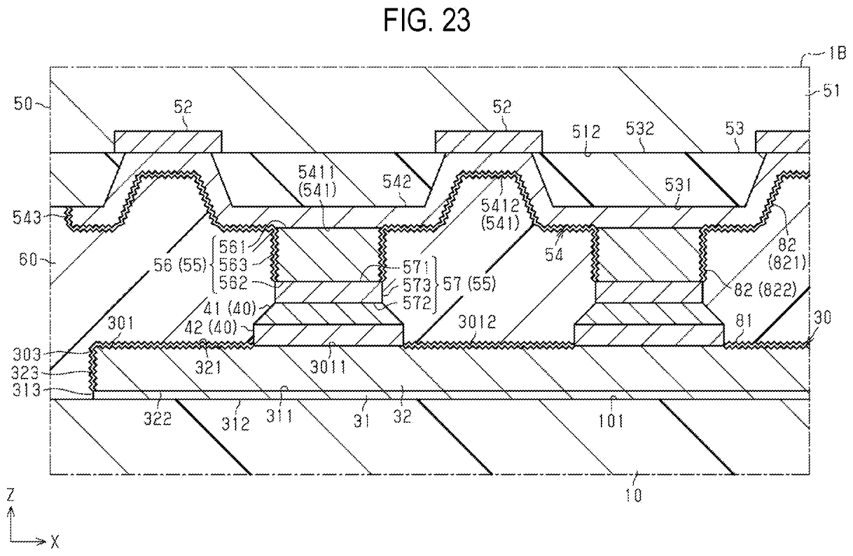

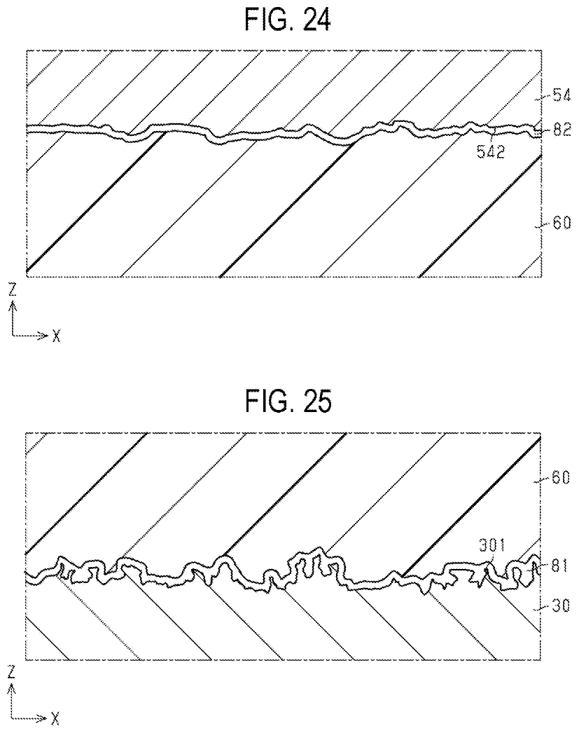

FIG. 21 is a cross-sectional view of the semiconductor device 1B of the present embodiment. FIGS. 22 and 23 are partially enlarged cross-sectional views of the semiconductor device 1B. FIG. 24 is an enlarged cross-sectional view showing an element wiring layer 54, a second adhesion layer 82, and a sealing resin 60. FIG. 25 is an enlarged cross-sectional view showing a mounting wiring layer 30, a first adhesion layer 81, and a sealing resin 60.

The semiconductor device 1B includes the first adhesion layer 81 and the second adhesion layer 82. The first adhesion layer 81 covers the surface of the mounting wiring layer 30. In other words, the semiconductor device 1B includes the first adhesion layer 81 which is in contact with the surface of the mounting wiring layer 30.

As shown in FIGS. 22 and 23, the mounting wiring layer 30 has a mounting wiring main surface 301, a mounting wiring back surface 302, and a mounting wiring side surface 303. The mounting wiring back surface 302 is in contact with the resin main surface 101 of the resin layer 10. The mounting wiring main surface 301 and the mounting wiring side surface 303 are rough surfaces having a larger surface roughness than the mounting wiring back surface 302. The first adhesion layer 81 is in contact with the mounting wiring main surface 301 and the mounting wiring side surface 303, which are rough surfaces.

A bonding portion 40 for mounting the semiconductor element 50 on the mounting wiring layer 30 is provided on the mounting wiring main surface 301 of the mounting wiring layer 30. A covered portion 3011 of the mounting wiring main surface 301, which is covered by the bonding portion 40, is a flat surface. The mounting wiring main surface 301 (an exposed portion 3012), which is exposed from the bonding portion 40, is a rough surface having a larger surface roughness than the mounting wiring back surface 302. The first adhesion layer 81 is in contact with the mounting wiring main surface 301 (the exposed portion 3012) which is exposed from the bonding portion 40.

The first adhesion layer 81 is an organic film. The first adhesion layer 81 contains a material for improving adhesion. The first adhesion layer 81 can further improve the adhesion between the mounting wiring layer 30 and the sealing resin 60 which is in contact with the mounting wiring layer 30.

In the present embodiment, the surface roughness (the arithmetic average roughness Ra) of the mounting wiring main surface 301 of the mounting wiring layer 30 is 0.16 μm or more. The coating film thickness of the first adhesion layer 81 is 40 nm or more and 120 nm or less. As a result, peeling between the mounting wiring main surface 301 of the mounting wiring layer 30 and the sealing resin 60 can be suppressed.

FIG. 30 shows evaluation results of the presence or absence of peeling with respect to the rough surface roughness and the coating film thickness. In FIG. 30, the surface roughness is the arithmetic average roughness Ra. The coating film thickness is the film thickness of the first adhesion layer 81. In FIG. 30, no peeling is observed in a hatched region.

The coating film thickness of the first adhesion layer 81 can also be adjusted according to the surface roughness of the mounting wiring main surface 301. As shown in FIG. 30, when the surface roughness is 0.30 μm or more, the occurrence of peeling can be suppressed in the first adhesion layer 81 having a coating film thickness smaller than 40 nm, as in the above embodiment. Further, by setting the surface roughness to 0.30 μm or more, the first adhesion layer 81 can be omitted, that is, it can be configured with the semiconductor device 1A of the first embodiment.

The mounting wiring layer 30 includes a metal layer 31 and a conductive layer 32. The metal layer 31 is composed of a material containing Ti. The conductive layer 32 is composed of a material containing Cu. The side surface 313 of the metal layer 31 is a flat surface. The main surface 321 and the side surface 323 of the conductive layer 32 are rough surfaces. The adhesion layer is in contact with the main surface 321 and the side surface 323 of the conductive layer 32, which are the rough surfaces. That is, the first adhesion layer 81 is in contact with the surface (the main surface 321 and the side surface 323) of the conductive layer 32 and is not in contact with the surface (the side surface 313) of the metal layer 31.

The element wiring layer 54 has an element wiring main surface 541, an element wiring back surface 542, and an element wiring side surface 543. The element wiring back surface 542 is in contact with the main surface 531 of the insulating film 53. The element wiring main surface 541 and the element wiring side surface 543 are rough surfaces having a larger surface roughness than the mounting wiring back surface 302 of the mounting wiring layer 30. The second adhesion layer 82 is in contact with the element wiring main surface 541 and the element wiring side surface 543, which are rough surfaces.

The second adhesion layer 82 is an organic film. The second adhesion layer 82 contains a material for improving adhesion. The second adhesion layer 82 can further improve the adhesion between the element wiring layer 54 and the sealing resin 60 which is in contact with the element wiring layer 54.

In the present embodiment, the surface roughness (the arithmetic average roughness Ra) of the element wiring main surface 541 of the element wiring layer 54 is 0.16 μm or more. The coating film thickness of the second adhesion layer 82 is 40 nm or more and 120 nm or less. As a result, peeling between the element wiring main surface 541 of the element wiring layer 54 and the sealing resin 60 can be suppressed.

FIG. 30 shows evaluation results of the presence or absence of peeling with respect to the rough surface roughness and the coating film thickness. In FIG. 30, the surface roughness is the arithmetic average roughness Ra. The coating film thickness is the film thickness of the second adhesion layer 82. In FIG. 30, no peeling is observed in a hatched region.

The coating film thickness of the second adhesion layer 82 can also be adjusted according to the surface roughness of the element wiring main surface 541. As shown in FIG. 30, when the surface roughness is 0.30 μm or more, the occurrence of peeling can be suppressed in the second adhesion layer 82 having a coating film thickness smaller than 40 nm, as in the above embodiment. Further, by setting the surface roughness to 0.30 μm or more, the second adhesion layer 82 can be omitted, that is, it can be configured with the semiconductor device 1A of the first embodiment.

The semiconductor element 50 includes an element electrode 55. The element electrode 55 is provided on the element wiring main surface 541 of the element wiring layer 54. A covered portion 5411 of the element wiring main surface 541, which is covered by the element electrode 55, is a flat surface. The element wiring main surface 541 exposed from the element electrode 55 is a rough surface having a larger surface roughness than the mounting wiring back surface 302 of the mounting wiring layer 30. The second adhesion layer 82 covers the element wiring main surface 541 (an exposed portion 5412) exposed from the element electrode 55.

The element electrode 55 includes a conductive layer 56 connected to the element wiring layer 54 and a barrier layer 57 connected to the conductive layer 56. The conductive layer 56 is composed of a material containing Cu. The side surface 563 of the conductive layer 56 is a rough surface having a larger surface roughness than the mounting wiring back surface 302 of the mounting wiring layer 30. The barrier layer 57 is composed of a material containing Ni. The side surface 573 of the barrier layer 57 is a flat surface. The second adhesion layer 82 is in contact with the surface (the side surface 563) of the conductive layer 56 and is not in contact with the surface (the side surface 573) of the barrier layer 57.

Therefore, the second adhesion layer 82 of the present embodiment includes a wiring covered portion 821 which is in contact with the surface of the element wiring layer 54 and an electrode covered portion 822 which is in contact with the conductive layer 56 of the element electrode 55. The second adhesion layer 82 covers the surface of the element wiring layer 54 of the semiconductor element 50. In other words, the semiconductor device 1B includes the second adhesion layer 82 (the wiring covered portion 821) which is in contact with the surface of the element wiring layer 54 of the semiconductor element 50. Further, the second adhesion layer 82 covers the surface of the conductive layer 56 constituting the element electrode 55 of the semiconductor element 50. In other words, the semiconductor device 1B includes the second adhesion layer 82 (the electrode covered portion 822) which is in contact with the surface of the conductive layer 56 of the element electrode 55.

The second adhesion layer 82 is an organic film. The second adhesion layer 82 contains a material for improving adhesion. The second adhesion layer 82 can further improve the adhesion between the element wiring layer 54 and the sealing resin 60 which is in contact with the element wiring layer 54. As a result, peeling of the sealing resin 60 from the element wiring layer 54 can be suppressed. Further, the second adhesion layer 82 can further improve the adhesion between the element electrode 55 and the sealing resin 60 which is in contact with the element electrode 55. As a result, peeling of the sealing resin 60 from the element electrode 55 can be suppressed.

### [Method of Manufacturing Semiconductor Device]

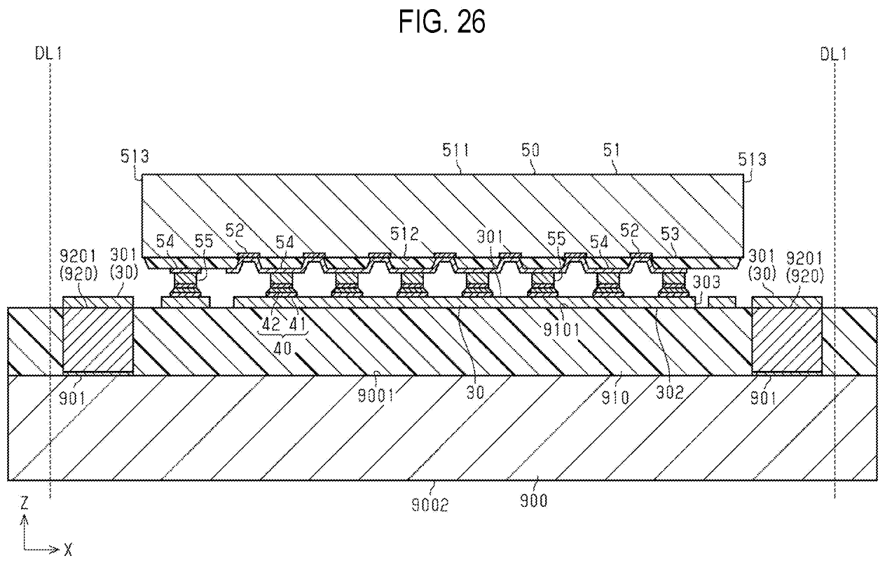

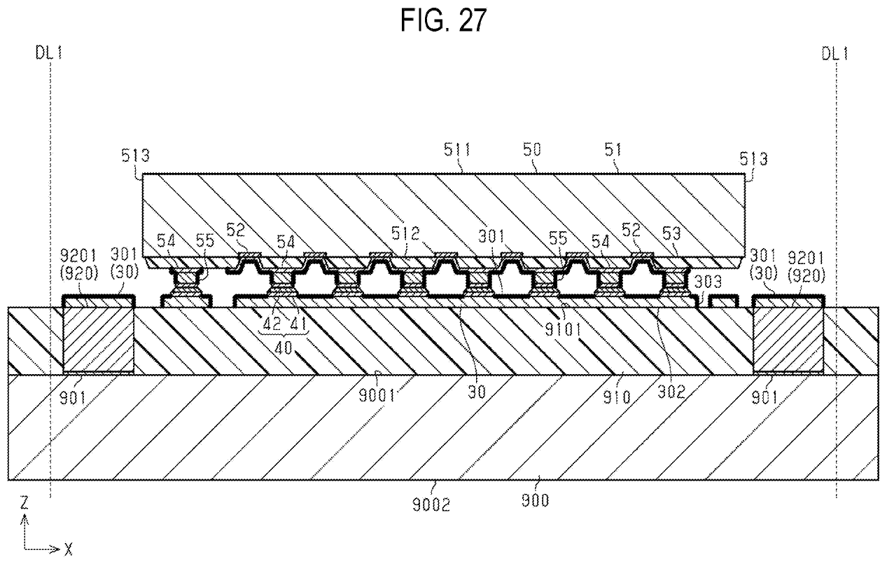

Next, a method of manufacturing the semiconductor device 1B of the present embodiment will be described. FIG. 26 shows a state in which the semiconductor element 50 has been mounted. FIG. 27 shows a state in which a roughening process has been performed. That is, the method of manufacturing the semiconductor device 1B of the present embodiment includes the steps of FIGS. 7 to 14 shown in the method of manufacturing the semiconductor device 1A of the first embodiment.

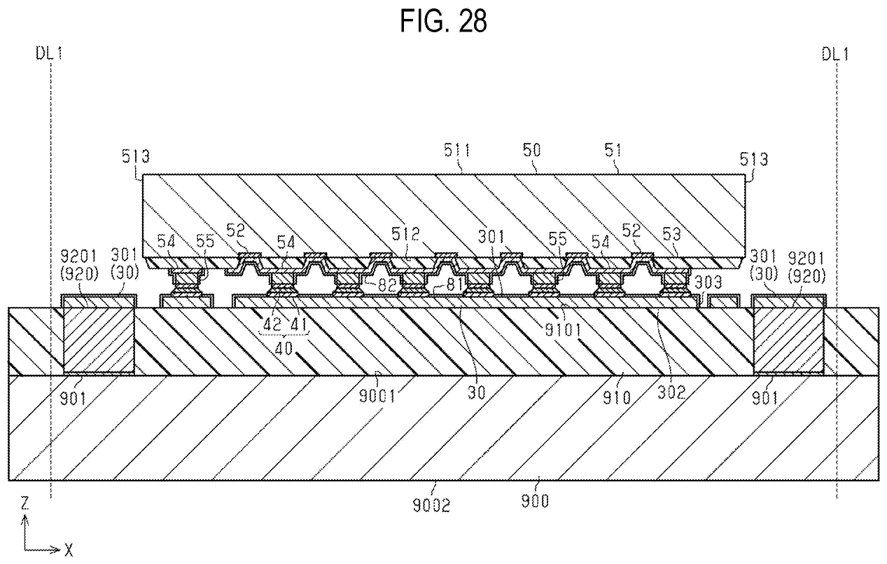

As shown in FIG. 28, the method of manufacturing the semiconductor device 1B includes a step of forming the first adhesion layer 81 and the second adhesion layer 82. The first adhesion layer 81 and the second adhesion layer 82 are formed by applying a liquid resin material by, for example, a spin coating method. The resin material (organic solution) for forming the first adhesion layer 81 and the second adhesion layer 82 easily adheres to the surface of Cu and hardly adheres to the surface of metal other than Cu. As a result, the first adhesion layer 81 is formed on the entire surface of the mounting wiring layer 30 on which the semiconductor element 50 is mounted, and the second adhesion layer 82 is formed on the entire surface of the element wiring layer 54 and the element electrode 55 of the mounted semiconductor element 50.

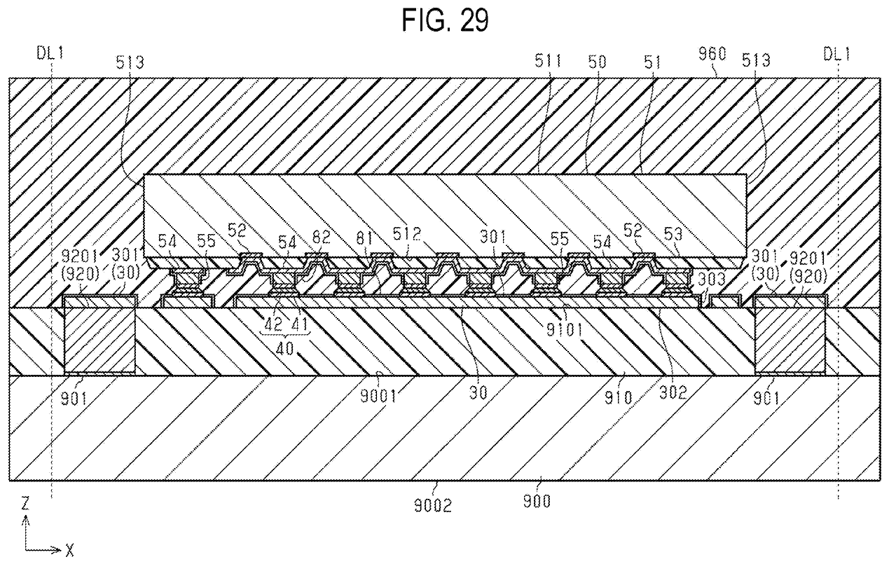

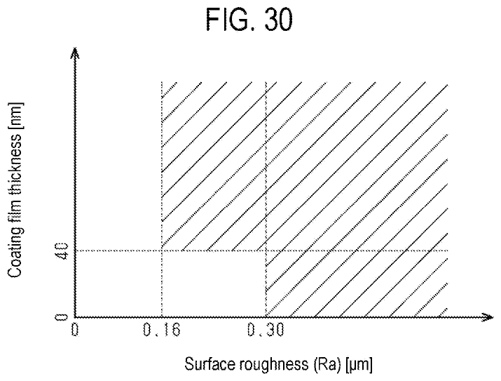

As shown in FIG. 29, the method of manufacturing the semiconductor device 1B includes a step of forming a resin layer 960. In this step, the resin layer 960 is formed by, for example, compression molding, as in the step shown in FIG. 15 of the first embodiment. The resin layer 960 is filled between the resin layer 910, the mounting wiring layer 30, and the semiconductor element 50 and is formed so as to be in contact with the surfaces of the first adhesion layer 81 and the second adhesion layer 82.

After this step, the semiconductor device 1B is formed through the steps shown in FIGS. 16 to 20 of the first embodiment.

### (Operation)

Next, the operation of the semiconductor device 1B of the present embodiment will be described.

The semiconductor device 1B of the present embodiment includes the first adhesion layer 81. The first adhesion layer 81 covers the surface of the mounting wiring layer 30. In other words, the semiconductor device 1B includes the first adhesion layer 81 which is in contact with the surface of the mounting wiring layer 30. The first adhesion layer 81 is an organic film. The first adhesion layer 81 contains a material for improving adhesion. The first adhesion layer 81 can further improve the adhesion between the mounting wiring layer 30 and the sealing resin 60 which is in contact with the mounting wiring layer 30.

The semiconductor device 1B includes the second adhesion layer 82. The element wiring layer 54 has the element wiring main surface 541, the element wiring back surface 542, and the element wiring side surface 543. The element wiring back surface 542 is in contact with the main surface 531 of the insulating film 53. The element wiring main surface 541 and the element wiring side surface 543 are rough surfaces having a larger surface roughness than the mounting wiring back surface 302 of the mounting wiring layer 30. The second adhesion layer 82 is in contact with the element wiring main surface 541 and the element wiring side surface 543, which are rough surfaces. The second adhesion layer 82 is an organic film. The second adhesion layer 82 contains a material for improving adhesion. The second adhesion layer 82 can further improve the adhesion between the element wiring layer 54 and the sealing resin 60 which is in contact with the element wiring layer 54.

FIG. 30 shows evaluation results of the presence or absence of peeling when the rough surface roughness and the coating film thickness are changed. In FIG. 30, no peeling is observed in a hatched region. In FIG. 30, the surface roughness is the arithmetic average roughness Ra. The coating film thickness is the film thickness of the first adhesion layer 81 and the second adhesion layer 82.

When the coating film thickness of the first adhesion layer 81 and the second adhesion layer 82 is 40 nm or more and the surface roughness is 0.16 μm or more, no peeling is observed. Even if the coating film thickness is less than 40 nm, no peeling is observed if the surface roughness is 0.30 μm or more. When the coating film thickness is 0 nm, that is, there is no first adhesion layer 81 and no second adhesion layer 82, that is, in the state of the semiconductor device 1A of the first embodiment, no peeling is observed if the surface roughness is 0.30 μm or more.

That is, by setting the surface roughness of the mounting wiring layer 30 and the element wiring layer 54 to be 0.3 μm or more, the first adhesion layer 81 and the second adhesion layer 82 can be omitted. By setting the coating film thickness of the first adhesion layer 81 and the second adhesion layer 82 to 40 nm, peeling of the mounting wiring layer 30 and the element wiring layer 54 having a rough surface having a surface roughness of 0.16 μm or more and less than 0.30 μm can be suppressed.

### (Effects)

As described above, according to the present embodiment, the following effects are obtained in addition to the effects of the first embodiment.

(2-1) The semiconductor device 1B of the present embodiment includes the first adhesion layer 81. The first adhesion layer 81 covers the surface of the mounting wiring layer 30. In other words, the semiconductor device 1B includes the first adhesion layer 81 which is in contact with the surface of the mounting wiring layer 30. The first adhesion layer 81 is an organic film. The first adhesion layer 81 contains a material for improving adhesion. The first adhesion layer 81 can further improve the adhesion between the mounting wiring layer 30 and the sealing resin 60 which is in contact with the mounting wiring layer 30.

(2-2) The semiconductor device 1B of the present embodiment includes the second adhesion layer 82. The element wiring layer 54 has the element wiring main surface 541, the element wiring back surface 542, and the element wiring side surface 543. The element wiring back surface 542 is in contact with the main surface 531 of the insulating film 53. The element wiring main surface 541 and the element wiring side surface 543 are rough surfaces having a larger surface roughness than the mounting wiring back surface 302 of the mounting wiring layer 30. The second adhesion layer 82 is in contact with the element wiring main surface 541 and the element wiring side surface 543, which are rough surfaces. The second adhesion layer 82 is an organic film. The second adhesion layer 82 contains a material for improving adhesion. The second adhesion layer 82 can further improve the adhesion between the element wiring layer 54 and the sealing resin 60 in contact with the element wiring layer 54.

### (Modifications)

The above embodiments can be modified, for example, as follows. The above embodiments and each of the following modifications can be combined with each other as long as there is no technical conflict. In the following modifications, the portions common to the above embodiments are denoted by the same reference numerals as those in the above embodiments, and explanation thereof will be omitted.

The semiconductor device manufacturing method may include a step of roughening the surface of the mounting wiring layer 30 and a step of roughening the surface of the element wiring layer 54. For example, the semiconductor element 50 having the surface of the element wiring layer 54 and the element electrode 55 as rough surfaces may be mounted on the mounting wiring layer 30. The surface of the mounting wiring layer 30 may be roughened before mounting the semiconductor element 50. Further, the surface of the mounting wiring layer 30 may be roughened after mounting the semiconductor element 50.

The second embodiment may have a configuration including a step of forming the first adhesion layer 81 and a step of forming the second adhesion layer 82. For example, the semiconductor element 50 formed with the second adhesion layer 82, which is in contact with the element wiring layer 54 and the element electrode 55, may be mounted on the mounting wiring layer 30. The first adhesion layer 81 which is in contact with the mounting wiring layer 30 may be formed before mounting the semiconductor element 50. Further, the first adhesion layer 81 may be formed after mounting the semiconductor element 50.

The external conductive film 70 may be omitted.

The external conductive film 70 may be configured in which either the first conductive film 71 or the second conductive film 72 is omitted.

In the step of roughening the surface of the terminal portion 20, an acidic solution may be used as the roughening solution.

The step of roughening the surface of the terminal portion 20 may be omitted.

### (Supplementary Notes)

The technical ideas that can be understood from the present disclosure are described below. It should be noted that the constituent elements described in supplementary notes are provided with reference numerals of the corresponding constituent elements in the embodiments for the purpose of assisting understanding, not for the purpose of limiting. The reference numerals are shown as examples for the sake of comprehension, and the constituent elements described in each supplementary note should not be limited to the constituent elements indicated by the reference numerals.

### (Supplementary Note 1)

A Semiconductor Device Includes:

a resin layer (10) having a resin main surface (101);

a mounting wiring layer (30) arranged on the resin main surface (101), and having a mounting wiring main surface (301) facing the same side as the resin main surface (101) and a mounting wiring back surface (302) facing the side of the resin main surface (101);

a semiconductor element (50) including an element wiring layer (54) that is mounted on the mounting wiring main surface (301), has an element wiring main surface (541) facing the side of the resin layer (10), and is connected to the mounting wiring layer (30); and
a sealing resin (60) that seals the mounting wiring layer (30) and the semiconductor element (50),
wherein the mounting wiring main surface (301) and the element wiring main surface (541) are rough surfaces having a larger surface roughness than the mounting wiring back surface (302).

### (Supplementary Note 2)

In the semiconductor device of Supplementary Note 1, the mounting wiring layer (30) has a mounting wiring side surface (303) connected to the mounting wiring main surface (301) and the mounting wiring back surface (302),
wherein the mounting wiring side surface (303) is a rough surface having a larger surface roughness than the mounting wiring back surface (302).

### (Supplementary Note 3)

The semiconductor device of Supplementary Note 1 or 2, further includes: a bonding portion (40) that is provided on the mounting wiring main surface (301) and to which the semiconductor element (50) is connected,
wherein the mounting wiring main surface (301) includes a flat first covered portion (3011) covered by the bonding portion (40), and a first exposed portion (3012) which is a rough surface having a larger surface roughness than the mounting wiring back surface (302) exposed from the bonding portion (40).

### (Supplementary Note 4)

In the semiconductor device of any one of Supplementary Notes 1 to 3, the semiconductor element (50) includes an element electrode (55) provided on the element wiring main surface (541),

wherein the element wiring main surface (541) includes a flat second covered portion (5411) covered by the element electrode (55), and a second exposed portion (5412) which is a rough surface having a larger surface roughness than the mounting wiring back surface (302) exposed from the element electrode (55).

### (Supplementary Note 5)

In the semiconductor device of Supplementary Note 4, the element electrode (55) includes a conductive layer (56) connected to the element wiring layer (54), and a barrier layer (57) connected to the conductive layer (56),
wherein the side surface (563) of the conductive layer (56) is a rough surface having a larger surface roughness than the mounting wiring back surface (302), and
wherein the side surface (573) of the barrier layer (57) is a flat surface.

### (Supplementary Note 6)

In the semiconductor device of any one of Supplementary Notes 1 to 5, the surface roughness of the mounting wiring main surface (301) is 0.3 μm or more.

### (Supplementary Note 7)

In the semiconductor device of any one of Supplementary Notes 1 to 6, wherein the surface roughness of the element wiring main surface (541) is 0.3 μm or more.

### (Supplementary Note 8)

The semiconductor device of any one of Supplementary Notes 1 to 5, further includes:

a first adhesion layer (81) in contact with the mounting wiring main surface (301); and

a second adhesion layer (82) in contact with the element wiring main surface (541).

### (Supplementary Note 9)

In the semiconductor device of Supplementary Note 8, the first adhesion layer (81) and the second adhesion layer (82) are organic films.

### (Supplementary Note 10)

In the semiconductor device of Supplementary Note 8 or 9, the film thickness of the first adhesion layer (81) is 40 nm or more, and the surface roughness of the mounting wiring main surface (301) is 0.16 μm or more.

### (Supplementary Note 11)

In the semiconductor device of any one of Supplementary Notes 8 to 10, the film thickness of the second adhesion layer (82) is 40 nm or more, and the surface roughness of the element wiring main surface (541) is 0.16 μm or more.

### (Supplementary Note 12)

In the semiconductor device of any one of Supplementary Notes 8 to 11, the film thickness of the first adhesion layer (81) is 120 nm or less.

### (Supplementary Note 13)

In the semiconductor device of any one of Supplementary Notes 8 to 12, the film thickness of the second adhesion layer (82) is 120 nm or less.

### (Supplementary Note 14)

In the semiconductor device of any one of Supplementary Notes 1 to 13, the resin layer (10) has a resin back surface (102) facing the opposite side of the resin main surface (101), and a through-hole (11) that penetrates the resin layer (10) from the resin main surface (101) to the resin back surface (102),
wherein the semiconductor device further includes a terminal portion (20) that is provided in the through-hole (11) and is connected to the mounting wiring layer (30).

### (Supplementary Note 15)

In the semiconductor device of Supplementary Note 14, the terminal portion (20) has a back surface (202) exposed from the resin back surface (102),
wherein the semiconductor device further includes an external conductive film (70) in contact with the back surface (202) of the terminal portion (20).

### (Supplementary Note 16)

In the semiconductor device of Supplementary Note 15, the terminal portion (20) has a side surface (204) exposed from the resin side surface (104) of the resin layer (10), and
wherein the external conductive film (70) has a first conductive film (71) which is in contact with the back surface (202) of the terminal portion (20), and a second conductive film (72) which is in contact with the side surface (204) of the terminal portion (20).

### (Supplementary Note 17)

A method of manufacturing a semiconductor device, includes:

forming a resin layer (10) having a resin main surface (101);

forming a mounting wiring layer (30) having a mounting wiring main surface (301) facing the same direction as the resin main surface (101) and a mounting wiring back surface (302) facing the side of the resin main surface (101), on the resin main surface (101);

mounting a semiconductor element (50) including an element wiring layer (54) having an element wiring main surface (541) facing the side of the resin main surface (101), on the mounting wiring layer (30);

making the mounting wiring main surface (301) a rough surface having a larger surface roughness than the mounting wiring back surface (302);

making the element wiring main surface (541) a rough surface having a larger surface roughness than the mounting wiring back surface (302); and

forming a sealing resin (60) that is in contact with the resin main surface (101) and seals the mounting wiring layer (30) and the semiconductor element (50).

### (Supplementary Note 18)

In the method of Supplementary Note 17, after the semiconductor element (50) is mounted on the mounting wiring layer (30), the mounting wiring main surface (301) and the element wiring main surface (541) are roughened at the same time.

### (Supplementary Note 19)

The method of Supplementary Note 17 or 18, further includes:

forming a first adhesion layer (81) which is in contact with the roughened mounting wiring main surface (301); and

forming a second adhesion layer (82) which is in contact with the roughened element wiring main surface (541).

### (Supplementary Note 20)

In the method of Supplementary Note 19, the first adhesion layer (81) and the second adhesion layer (82) are formed at the same time.

### (Supplementary Note 21)

The method of any one of Supplementary Notes 17 to 20, further includes:

forming a terminal portion (920) on the main surface (9001) of a support substrate (900);

roughening the surface of the terminal portion (920);

forming a first resin layer (910) which is in contact with the surface of the terminal portion (920); and

forming the resin layer (910) having the resin main surface (9101) and exposing the main surface (9201) of the terminal portion (920) by grinding the first resin layer (910),

wherein the mounting wiring layer (30) is arranged on the resin main surface (9101) and is in contact with the main surface (9201) of the terminal portion (920).

### (Supplementary Note 22)

The method of Supplementary Note 21, further includes:

removing the support substrate (900) and exposing the back surface (202) of the terminal portion (20) from the resin layer (10);

forming a separation groove (904) with the resin layer (10) facing the sealing resin (60), and exposing the side surface (204) of the terminal portion (20); and

forming an external conductive film (70) in contact with the back surface (202) and the side surface (204) of the terminal portion (20).

The above descriptions are merely examples. Those skilled in the art will appreciate that more possible combinations and substitutions are possible beyond the constituent elements and methods (manufacturing processes) listed for the purposes of illustrating the techniques of the present disclosure. The present disclosure is intended to include all alternatives, modifications, and changes included within the scope of the present disclosure, including the claims.

According to the present disclosure in some embodiments, it is possible to provide a semiconductor device and a method of manufacturing the semiconductor device, which are capable of improving adhesion.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a resin layer having a resin main surface;
a mounting wiring layer arranged on the resin main surface, and having a mounting wiring main surface facing the same side as the resin main surface and a mounting wiring back surface facing the side of the resin main surface;
a semiconductor element including an element wiring layer which is mounted on the mounting wiring main surface, has an element wiring main surface facing the side of the resin layer, and is connected to the mounting wiring layer; and
a sealing resin which seals the mounting wiring layer and the semiconductor element,
wherein the mounting wiring main surface and the element wiring main surface are rough surfaces having a larger surface roughness than the mounting wiring back surface.

2. The semiconductor device of claim 1, wherein the mounting wiring layer has a mounting wiring side surface connected to the mounting wiring main surface and the mounting wiring back surface, and
wherein the mounting wiring side surface is a rough surface having a larger surface roughness than the mounting wiring back surface.

3. The semiconductor device of claim 1, further comprising: a bonding portion which is provided on the mounting wiring main surface and connected to the semiconductor element,
wherein the mounting wiring main surface includes a flat first covered portion covered by the bonding portion, and a first exposed portion which is a rough surface having a larger surface roughness than the mounting wiring back surface exposed from the bonding portion.

4. The semiconductor device of claim 2, further comprising: a bonding portion which is provided on the mounting wiring main surface and connected to the semiconductor element,
wherein the mounting wiring main surface includes a flat first covered portion covered by the bonding portion, and a first exposed portion which is a rough surface having a larger surface roughness than the mounting wiring back surface exposed from the bonding portion.

5. The semiconductor device of claim 1, wherein the semiconductor element includes an element electrode which is provided on the element wiring main surface, and
wherein the element wiring main surface includes a flat second covered portion covered by the element electrode, and a second exposed portion which is a rough surface having a larger surface roughness than the mounting wiring back surface exposed from the element electrode.

6. The semiconductor device of claim 5, wherein the element electrode includes a conductive layer connected to the element wiring layer, and a barrier layer connected to the conductive layer,
wherein a side surface of the conductive layer is a rough surface having a larger surface roughness than the mounting wiring back surface, and
wherein a side surface of the barrier layer is a flat surface.

7. The semiconductor device of claim 1, wherein a surface roughness of the mounting wiring main surface is 0.3 μm or more.

8. The semiconductor device of claim 1, wherein a surface roughness of the element wiring main surface is 0.3 μm or more.

9. The semiconductor device of claim 1, further comprising:
a first adhesion layer in contact with the mounting wiring main surface; and
a second adhesion layer in contact with the element wiring main surface.

10. The semiconductor device of claim 9, wherein the first adhesion layer and the second adhesion layer are organic films.

11. The semiconductor device of claim 9, wherein a film thickness of the first adhesion layer is 40 nm or more, and a surface roughness of the mounting wiring main surface is 0.16 μm or more.

12. The semiconductor device of claim 9, wherein a film thickness of the second adhesion layer is 40 nm or more, and a surface roughness of the element wiring main surface is 0.16 μm or more.

13. The semiconductor device of claim 1, wherein the resin layer has a resin back surface facing the opposite side of the resin main surface, and a through-hole that penetrates the resin layer from the resin main surface to the resin back surface, and
wherein the semiconductor device further comprises a terminal portion provided in the through-hole and connected to the mounting wiring layer.

14. The semiconductor device of claim 13, wherein the terminal portion has a back surface exposed from the resin back surface, and
wherein the semiconductor device further comprises an external conductive film in contact with the back surface of the terminal portion.

15. A method of manufacturing a semiconductor device, comprising:
forming a resin layer having a resin main surface;
forming a mounting wiring layer, which has a mounting wiring main surface facing a same direction as the resin main surface and a mounting wiring back surface facing the side of the resin main surface, on the resin main surface;
mounting a semiconductor element, which includes an element wiring layer having an element wiring main surface facing a side of the resin main surface, on the mounting wiring layer;
making the mounting wiring main surface a rough surface having a larger surface roughness than the mounting wiring back surface;
making the element wiring main surface a rough surface having a larger surface roughness than the mounting wiring back surface; and
forming a sealing resin that is in contact with the resin main surface and seals the mounting wiring layer and the semiconductor element.

16. The method of claim 15, wherein after the semiconductor element is mounted on the mounting wiring layer, the mounting wiring main surface and the element wiring main surface are roughened simultaneously.

17. The method of claim 15, further comprising:
forming a first adhesion layer in contact with the roughened mounting wiring main surface; and
forming a second adhesion layer in contact with the roughened element wiring main surface.

18. The method of claim 17, wherein the first adhesion layer and the second adhesion layer are formed at the same time.

19. The method of claim 15, further comprising:
forming a terminal portion on a main surface of a support substrate;
roughening a surface of the terminal portion;
forming a first resin layer in contact with the surface of the terminal portion; and
forming the resin layer having the resin main surface and exposing a main surface of the terminal portion by grinding the first resin layer,
wherein the mounting wiring layer is arranged on the resin main surface and is in contact with the main surface of the terminal portion.

20. The method of claim 19, further comprising:
removing the support substrate and exposing a back surface of the terminal portion from the resin layer;
forming a separation groove, which faces the sealing resin, in the resin layer, and exposing a side surface of the terminal portion; and
forming an external conductive film in contact with the back surface and the side surface of the terminal portion.
